(19) United States
(12) Patent Application Publication
(10) Pub. No.: US 2026/0206303 A1
(43) Pub. Date: Jul. 16, 2026

(54) SEMICONDUCTOR DEVICE

(71) Applicant: Samsung Electronics Co., Ltd., Suwon-si (KR)

(72) Inventors: Kyungbin CHUN, Suwon-si (KR); Dongwoo KIM, Suwon-si (KR); Seokhoon KIM, Suwon-si (KR); Pankwi PARK, Suwon-si (KR); Dongsuk SHIN, Suwon-si (KR); Ryong HA, Suwon-si (KR)

(73) Assignee: Samsung Electronics Co., Ltd., Suwon-si (KR)

(21) Appl. No.: 19/444,657

(22) Filed: Jan. 9, 2026

(30) Foreign Application Priority Data
Jan. 16, 2025 (KR) 10-2025-0006832

(51) Int. Cl. H10D 84/83; H10D 30/00; H10D 30/01; H10D 30/43; H10D 62/10; H10D 62/13; H10D 62/832; H10D 64/23; H10D 84/01; H10W 20/41

(52) U.S. Cl. CPC H10D 84/832; H10D 30/43; H10D 30/503; H10D 30/506; H10D 62/121; H10D 62/151; H10D 62/832; H10D 64/256; H10D 84/8312; H10W 20/427; H10W 20/435; H10D 30/014; H10D 30/019; H10D 84/013; H10D 84/0149

(57) ABSTRACT

A semiconductor device may include an active pattern extending in a first horizontal direction on the top surface of a substrate, a gate electrode on the active pattern and extending in a second horizontal direction, a first source/drain pattern including a lower epitaxial region and an upper epitaxial region, and a first source/drain contact connected to the first source/drain pattern. The active pattern may include a fin-type active pattern. The first source/drain pattern may be connected to the fin-type active pattern. The upper epitaxial region may include an epitaxial recess that may be inwardly recessed from a surface of the fin-type active pattern. The lower epitaxial region may be arranged along an inner wall of the epitaxial recess. The first source/drain contact may be arranged in the epitaxial recess and in a power contact hole passing through the substrate and the fin-type active pattern.

### CROSS-REFERENCE TO RELATED APPLICATION

This application is based on and claims priority under 35 U.S.C. § 119 to Korean Patent Application No. 10-2025-0006832, filed on Jan. 16, 2025, in the Korean Intellectual Property Office, the disclosure of which is incorporated by reference herein in its entirety.

### BACKGROUND

Inventive concepts relate to a semiconductor device, and more particularly, to a semiconductor device including a field-effect transistor (FET).

Semiconductor devices may include an integrated circuit composed of FETs, e.g., metal-oxide semiconductor (MOS) FETs. As the size and design rules of semiconductor devices have been gradually reduced, the scaling-down of FETs has accelerated.

As FETs are scaled down, the operating characteristics of semiconductor devices may deteriorate. Therefore, there is ongoing research into various methods of forming semiconductors having excellent performance while being capable of overcoming limitations of high integration of semiconductor devices.

### SUMMARY

Inventive concepts relate to a semiconductor device including a field-effect transistor having improved electrical characteristics and device reliability.

According to an embodiment, a semiconductor device may include a substrate with a top surface of the substrate being opposite a bottom surface of the substrate in a vertical direction; an active pattern extending in a first horizontal direction on the top surface of the substrate, the active pattern including a fin-type active pattern protruding from the top surface of the substrate; a gate electrode on the active pattern and extending in a second horizontal direction, the second horizontal direction being perpendicular to the first horizontal direction; a first source/drain pattern connected to the fin-type active pattern, the first source/drain pattern including a lower epitaxial region and an upper epitaxial region, the upper epitaxial region including an epitaxial recess that is inwardly recessed from a surface of the fin-type active pattern, and the lower epitaxial region being arranged along an inner wall of the epitaxial recess, wherein the substrate, the fin-type active pattern, and a lower surface of the first source/drain pattern may define a power contact hole passing through substrate and the fin-type active pattern; a first source/drain contact connected to the first source/drain pattern, the first source/drain contact extending through the power contact hole into the epitaxial recess; and a contact silicide film between the first source/drain contact and the first source/drain pattern, the contact silicide film being on an inner wall of the power contact hole, the contact silicide film being in contact with the lower epitaxial region along the inner wall of the epitaxial recess.

According to an embodiment, a semiconductor device may include a substrate with a top surface of the substrate being opposite a bottom surface of the substrate in a vertical direction; an active pattern extending in a first horizontal direction on the top surface of the substrate, the active pattern including a fin-type active pattern protruding from the top surface of the substrate; a gate electrode on the active pattern and extending in a second horizontal direction, the second horizontal direction being perpendicular to the first horizontal direction; a first source/drain pattern connected to the fin-type active pattern, the first source/drain pattern including a cylindrical epitaxial region in the fin-type active pattern, a lower epitaxial region, and an upper epitaxial region in the cylindrical epitaxial region, the cylindrical epitaxial region being arranged on the fin-type active pattern, the upper epitaxial region including an epitaxial recess that is inwardly recessed from a surface of the fin-type active pattern, and the lower epitaxial region being arranged along an inner wall of the epitaxial recess, wherein the substrate, the fin-type active pattern, and a lower surface of the first source/drain pattern define a power contact hole passing through the substrate and the fin-type active pattern; a first source/drain contact connected to the first source/drain pattern, the first source/drain contact extending through the power contact hole into the epitaxial recess; and a contact silicide film between the first source/drain contact and the first source/drain pattern, the contact silicide film being on an inner wall of the power contact hole, the contact silicide film being in contact with the lower epitaxial region along the inner wall of the epitaxial recess.

According to an embodiment, a semiconductor device may include a substrate with a top surface of the substrate being opposite a bottom surface of the substrate in a vertical direction; an active pattern extending in a first horizontal direction on the top surface of the substrate, the active pattern including a fin-type active pattern and a sheet-type active pattern on the fin-type active pattern, the fin-type active pattern protruding from the top surface of the substrate, a first end of the sheet-type active pattern being opposite a second end of the sheet-type active pattern in the first horizontal direction; a gate electrode on the active pattern, the gate electrode extending in a second horizontal direction and surrounding the sheet-type active pattern, the second horizontal direction being perpendicular to the first horizontal direction; a first source/drain pattern connected to the fin-type active pattern and connected to the first end of the sheet-type active pattern, the first source/drain pattern including a lower epitaxial region and a first upper epitaxial region, the first upper epitaxial region including an epitaxial recess that is inwardly recessed from a surface of the fin-type active pattern, and the lower epitaxial region being arranged along an inner wall of the epitaxial recess, wherein the substrate, the fin-type active pattern, and a lower surface of the first source/drain pattern define a power contact hole passing through the substrate and the fin-type active pattern; a second source/drain pattern in contact with the fin-type active pattern and connected to the second end of the sheet-type active pattern, the second source/drain pattern including a second upper epitaxial region; a first source/drain contact connected to the first source/drain pattern, the first source/drain contact extending through the power contact hole into the epitaxial recess; a second source/drain contact on the fin-type active pattern and connected to the second source/drain pattern; a first contact silicide film between the first source/drain contact and the first source/drain pattern, the first contact silicide film being on an inner wall of the power contact hole, the first contact silicide film being in contact with the lower epitaxial region arranged along the inner wall of the epitaxial recess; and a second contact silicide film between the second source/drain contact and the second source/drain pattern, the second contact silicide film being in contact with the second upper epitaxial region.

According to an embodiment, a method of manufacturing a semiconductor device may include forming an active pattern extending in a first horizontal direction on a top surface of a substrate, the top surface of the substrate being opposite a bottom surface of the substrate in a vertical direction, and the active pattern including a fin-type active pattern protruding from the top surface of the substrate; forming a first upper source/drain region and a second upper source/drain region on the fin-type active pattern; forming a gate structure on the substrate, the gate structure including a gate electrode on the active pattern and between the first upper source/drain region and the second upper source/drain region in a plan view, the gate electrode extending in a second horizontal direction, the second horizontal direction being perpendicular to the first horizontal direction; forming a power contact hole through the substrate and a part of the first upper source/drain region such that a lower surface of the first upper source/drain region defines an epitaxial recess, the power contact hole extending in the vertical direction from the bottom surface of the substrate through the substrate and the fin-type active pattern into the first upper source/drain region; forming a first source/drain pattern by forming a lower epitaxial region along the epitaxial recess of the first upper source/drain region, the lower epitaxial region being in an upper portion of the power contact hole; forming a first source/drain contact connected to the first source/drain pattern, the first source/drain contact extending through the power contact hole to contact the lower epitaxial region. The forming the first source/drain contact may include forming a first contact silicide film between the first source/drain contact and the first source/drain pattern. The first contact silicide film may be on an inner wall of the power contact hole. The first contact silicide film may be in contact with the lower epitaxial region along the inner wall of the epitaxial recess.

In some embodiments, the method may further include forming a second source/drain contact extending into the second upper source/drain region. The forming the second source/drain contact may include forming a second contact silicide film between the second source/drain contact and the second upper source/drain region.

In some embodiments, the first source/drain pattern may include an upper epitaxial region corresponding to a remaining portion of the first upper source/drain region after the lower epitaxial region is formed. The lower epitaxial region and the upper epitaxial region may include a silicon-germanium compound. A concentration of germanium in the lower epitaxial region may be less than a concentration of germanium in the upper epitaxial region.

In some embodiments, a distance from a surface of the fin-type active pattern to a topmost surface of the lower epitaxial region may be less than or equal to a distance from the topmost surface of the lower epitaxial region to a top surface of the upper epitaxial region, or the distance from the surface of the fin-type active pattern to the topmost surface of the lower epitaxial region may be greater than the distance from the topmost surface of the lower epitaxial region to the top surface of the upper epitaxial region.

In some embodiments, the method may further include forming a power line on the bottom surface of the substrate. The first source/drain contact may electrically connect the first source/drain pattern and the power line to each other.

### BRIEF DESCRIPTION OF THE DRAWINGS

Embodiments will be more clearly understood from the following detailed description taken in conjunction with the accompanying drawings in which:

FIG. 1 is a layout diagram of a semiconductor device according to an embodiment;

FIG. 2 is a cross-sectional view of the semiconductor device, taken along line A-A in FIG. 1;

FIG. 3 is a cross-sectional view of the semiconductor device, taken along line B-B in FIG. 1;

FIG. 4 illustrates cross-sectional views of the semiconductor device, taken along line C-C and line D-D in FIG. 1;

FIG. 5 is an enlarged view of a region P in FIG. 2;

FIG. 6 is an enlarged view of a region Q in FIG. 4;

FIGS. 7 and 8 are cross-sectional views of a semiconductor device according to an embodiment;

FIG. 9 is an enlarged view of a region Q-1 in FIG. 8;

FIGS. 10 and 11 are cross-sectional views of a semiconductor device according to an embodiment;

FIG. 12 is an enlarged view of a region Q-2 in FIG. 11;

FIGS. 13 and 14 are cross-sectional views of a semiconductor device according to an embodiment;

FIG. 15 is an enlarged view of a region Q-3 in FIG. 14; and

FIGS. 16 to 23 are cross-sectional views illustrating a method of manufacturing a semiconductor device, according to an embodiment.

### DETAILED DESCRIPTION OF THE EMBODIMENTS

Hereinafter, embodiments are described in detail with reference to the accompanying drawings. Embodiments may have only one implementation or may be implemented in combination of one or more embodiments. Accordingly, inventive concepts are not limited to one embodiment.

As used herein, the singular forms “a”, “an”, and “the” are intended to include the plural forms as well, unless the context clearly indicates otherwise. The drawings may be exaggerated for clarity.

While the terms, “first,” “second”, etc. may be used to describe various elements, such elements must not be limited to the above terms. These terms are used only to distinguish one device or element from another. Accordingly, it is to be understood that first devices or elements described below may be second devices or elements within the scope of inventive concepts.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

A transistor, e.g., a multi-bridge channel field-effect transistor (MBC FET), including a nanowire or a nanosheet is illustrated in the drawings of semiconductor devices according to some embodiments, but embodiments are not limited thereto. In some embodiments, a semiconductor device may also be applied to a fin-type transistor, e.g., a FinFET, including a channel region having a fin-shaped pattern.

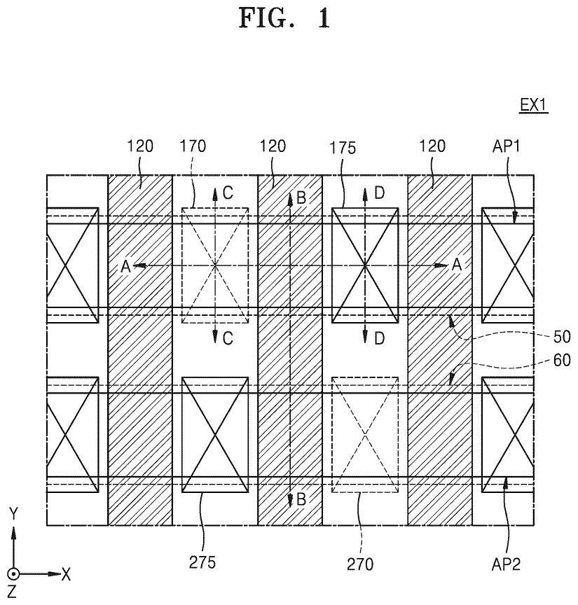

FIG. 1 is a layout diagram of a semiconductor device according to an embodiment.

A semiconductor device EX1 may include a first active pattern AP1, a second active pattern AP2, a plurality of gate electrodes 120, a first source/drain contact 170, a second source/drain contact 175, a third source/drain contact 270, a fourth source/drain contact 275, a first power line 50, and a second power line 60.

The first active pattern AP1 and the second active pattern AP2 may extend in a first horizontal direction (e.g., an X direction) and may be spaced apart from each other in a second horizontal direction (e.g., a Y direction). The first active pattern AP1 and the second active pattern AP2 may be adjacent to each other in the second horizontal direction (the Y direction).

Although the first active pattern AP1 is depicted as an active pattern closest to the second active pattern AP2, embodiments are not limited thereto. One or more active patterns may be arranged between the first active pattern AP1 and the second active pattern AP2.

In some embodiments, the first active pattern AP1 may include a region in which a p-type transistor is formed, and the second active pattern AP2 may include a region in which an n-type transistor is formed. In some embodiments, each of the first active pattern AP1 and the second active pattern AP2 may include a region in which a p-type transistor or an n-type transistor is formed.

The gate electrodes 120 may each cross the first active pattern AP1 and the second active pattern AP2. The gate electrodes 120 may extend in the second horizontal direction (the Y direction) and may be spaced apart from each other in the first horizontal direction (the X direction).

The first source/drain contact 170 and the second source/drain contact 175 may respectively overlap portions of the first active pattern AP1, which are respectively at opposite sides of one of the gate electrodes 120. The first source/drain contact 170 may correspond to a power contact connected at the bottom of a substrate, as described below. The second source/drain contact 175 may correspond to a power contact connected at the top of the substrate, as described below.

The third source/drain contact 270 and the fourth source/drain contact 275 may respectively overlap portions of the second active pattern AP2, which are respectively at opposite sides of one of the gate electrodes 120. The third source/drain contact 270 may correspond to a power contact connected at the bottom of the substrate, as described below. The fourth source/drain contact 275 may correspond to a power contact connected at the top of the substrate, as described below.

The first source/drain contact 170 and the third source/drain contact 270 may be arranged in a diagonal direction in a plan view. The second source/drain contact 175 and the fourth source/drain contact 275 may be arranged in a diagonal direction in a plan view.

The first power line 50 and the second power line 60 may be respectively below the first active pattern AP1 and the second active pattern AP2. In some embodiments, the first power line 50 and the second power line 60 may extend in the first horizontal direction (the X direction) and may be spaced apart from each other in the second horizontal direction (the Y direction).

The first power line 50 and the second power line 60 may extend in the first horizontal direction (the X direction), as shown in FIG. 1, but are not limited thereto. As described below, the first power line 50 and the second power line 60 may be arranged on the bottom surface of the substrate.

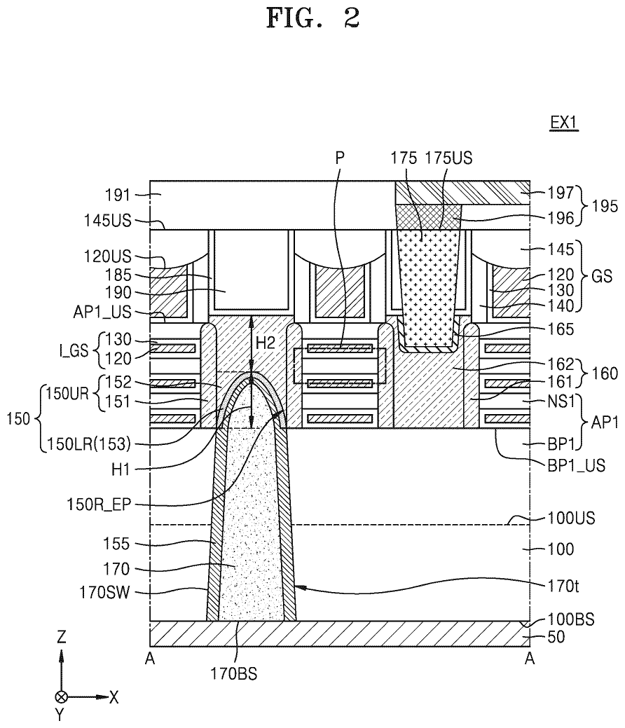

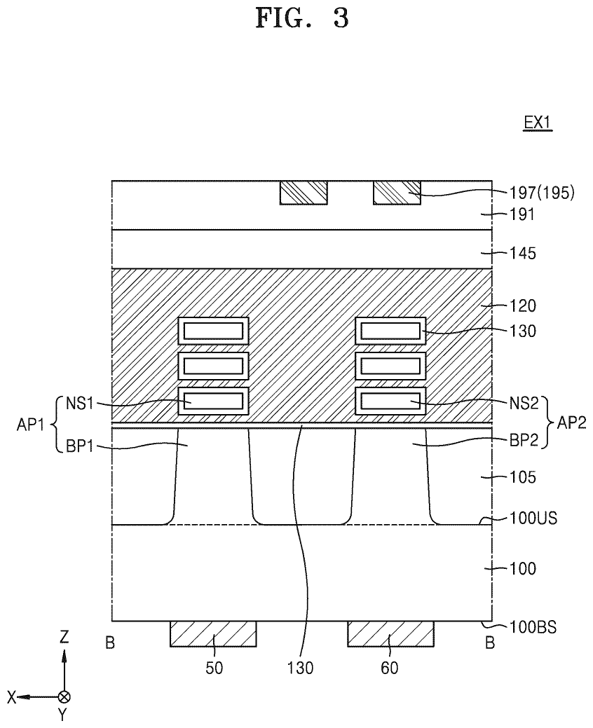

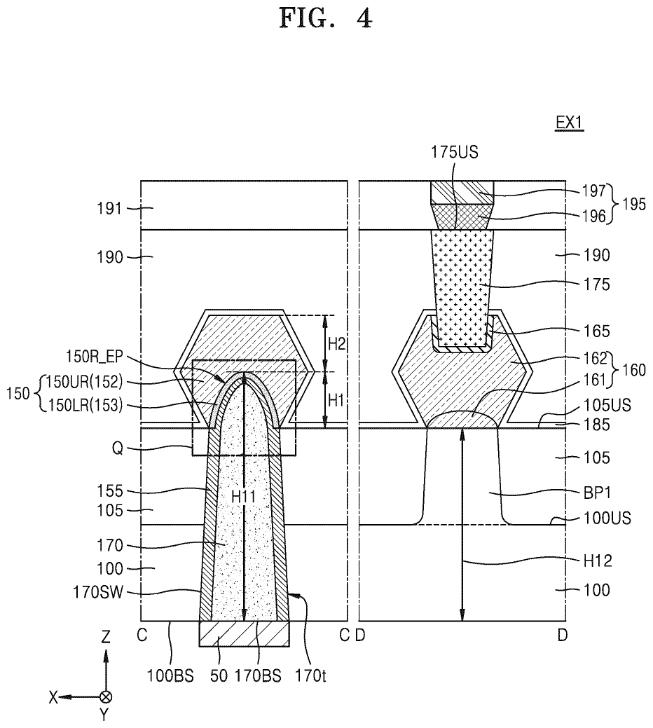

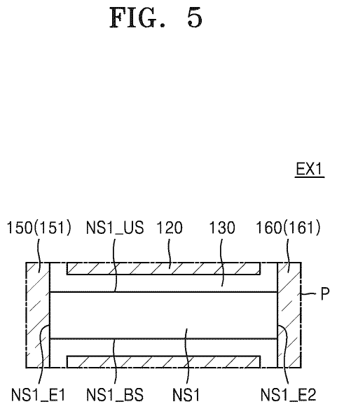

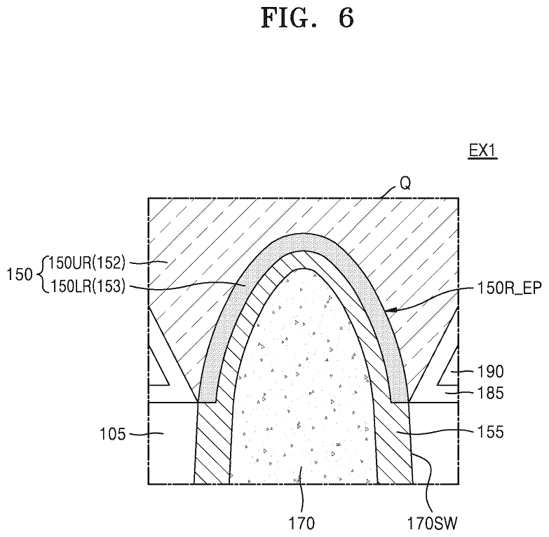

FIG. 2 is a cross-sectional view of the semiconductor device, taken along line A-A in FIG. 1. FIG. 3 is a cross-sectional view of the semiconductor device, taken along line B-B in FIG. 1. FIG. 4 illustrates cross-sectional views of the semiconductor device, taken along line C-C and line D-D in FIG. 1. FIG. 5 is an enlarged view of a region P in FIG. 2. FIG. 6 is an enlarged view of a region Q in FIG. 4.

The semiconductor device EX1 may include the first active pattern AP1, the second active pattern AP2, the plurality of gate electrodes 120, a first source/drain pattern 150, a second source/drain pattern 160, the first source/drain contact 170, and the second source/drain contact 175. The elements of the semiconductor device EX1 may form a field-effect transistor (FET).

A substrate 100 may include a top surface 100US and a bottom surface 100BS opposite to each other in a vertical direction (e.g., a Z direction). In some embodiments, the substrate 100 may include a semiconductor material or a semiconductor-on-insulator, such as bulk silicon or silicon-on-insulator (SOI). In some embodiments, the substrate 100 may include a silicon substrate.

The first active pattern AP1 and the second active pattern AP2 may be arranged on the substrate 100. The first active pattern AP1 and the second active pattern AP2 may be arranged on the top surface 100US of the substrate 100.

Each of the first active pattern AP1 and the second active pattern AP2 may include a multi-channel active pattern. The first active pattern AP1 may include a first fin-type active pattern BP1 and a plurality of first sheet-type active patterns NS1. The second active pattern AP2 may include a second fin-type active pattern BP2 and a plurality of second sheet-type active patterns NS2. The first sheet-type active patterns NS1 and the second sheet-type active patterns NS2 may include a nanosheet.

The first fin-type active pattern BP1 and the second fin-type active pattern BP2 may protrude from the top surface 100US of the substrate 100. Each of the first fin-type active pattern BP1 and the second fin-type active pattern BP2 may have a fin shape. The first fin-type active pattern BP1 may be spaced apart from the second fin-type active pattern BP2 in the second horizontal direction (the Y direction). The first fin-type active pattern BP1 and the second fin-type active pattern BP2 may be separated from each other by a fin trench extending in the first horizontal direction (the X direction). The top surface 100US of the substrate 100 may correspond to the bottom surface of the fin trench.

The first sheet-type active patterns NS1 may be arranged above the first fin-type active pattern BP1. The first sheet-type active patterns NS1 may be spaced apart from the first fin-type active pattern BP1 in the vertical direction (the Z direction). The first sheet-type active patterns NS1 may be arranged above the top surface 100US of the substrate 100.

The second sheet-type active patterns NS2 may be arranged above the second fin-type active pattern BP2. The second sheet-type active patterns NS2 may be spaced apart from the second fin-type active pattern BP2 in the vertical direction (the Z direction). The second sheet-type active patterns NS2 may be arranged above the top surface 100US of the substrate 100.

The vertical direction (the Z direction) may correspond to the thickness direction of the substrate 100. Although three first sheet-type active patterns NS1 and three second sheet-type active patterns NS2 are arranged in the vertical direction (the Z direction), this is just for convenience of description, and embodiments are not limited thereto.

As shown in FIG. 5, each of the first sheet-type active patterns NS1 may include a top surface NS1_US and a bottom surface NS1_BS. The top surface NS1_US of a first sheet-type active pattern NS1 may be opposite to the bottom surface NS1_BS of the first sheet-type active pattern NS1 in the vertical direction (the Z direction). The bottom surface NS1_BS of the first sheet-type active pattern NS1 may face the substrate 100.

The first sheet-type active pattern NS1 may also include a first end NS1_E1 and a second end NS1_E2. The first end NS1_E1 of the first sheet-type active pattern NS1 may be spaced apart from the second end NS1_E2 of the first sheet-type active pattern NS1 in the first horizontal direction (the X direction). In other words, the first end NS1_E1 and the second end NS1_E2 may be opposite each other in the X direction. The first end NS1_E1 and the second end NS1_E2 of the first sheet-type active pattern NS1 may be respectively connected to the first and second source/drain patterns 150 and 160 described below.

The first sheet-type active patterns NS1 may include a first topmost sheet-type active pattern that is farthest from the substrate 100. A top surface AP1_US of the first active pattern AP1 may correspond to the top surface of the first topmost sheet-type active pattern among the first sheet-type active patterns NS1. The descriptions of the second sheet-type active patterns NS2 may be substantially the same as those of the first sheet-type active patterns NS1.

Each of the first fin-type active pattern BP1 and the second fin-type active pattern BP2 may be formed by etching a portion of the substrate 100 or may include an epitaxial layer grown from the substrate 100. The first fin-type active pattern BP1 and the second fin-type active pattern BP2 may include a semiconductor material, such as silicon or germanium.

The first fin-type active pattern BP1 and the second fin-type active pattern BP2 may include a compound semiconductor, e.g., a Group IV-IV compound semiconductor or a Group III-V compound semiconductor. For example, the Group IV-IV compound semiconductor may include a binary compound, and/or a ternary compound including at least two selected from the group consisting of carbon (C), silicon (Si), germanium (Ge), and tin (Sn). For example, the Group IV-IV compound semiconductor may include a compound obtained by doping the binary compound or the ternary compound as above with a Group IV element.

The Group III-V compound semiconductor include one of a binary compound, a ternary compound, and a quaternary compound that may each include, as a Group III element, at least one selected from the group consisting of aluminum (Al), gallium (Ga), and indium (In) and, as a Group V element, at least one selected from the group consisting of phosphorus (P), arsenic (As), and antimony (Sb).

The first sheet-type active pattern NS1 and the second sheet-type active pattern NS2 may include a semiconductor material, such as silicon or germanium, a Group IV-IV compound semiconductor, or a Group III-V compound semiconductor. The width of the first sheet-type active patterns NS1 in the second horizontal direction (the Y direction) may increase or decrease in proportion to the width of the first fin-type active pattern BP1 in the second horizontal direction (the Y direction). The width of the second sheet-type active patterns NS2 in the second horizontal direction (the Y direction) may increase or decrease in proportion to the width of the second fin-type active pattern BP2 in the second horizontal direction (the Y direction).

Although it is illustrated in FIG. 3 that the first sheet-type active patterns NS1 have the same width in the second horizontal direction (the Y direction), embodiments are not limited thereto. A field insulating film 105 may be arranged on the top surface 100US of the substrate 100. The field insulating film 105 may fill a fin trench that separates the first fin-type active pattern BP1 from the second fin-type active pattern BP2. For example, the fin trench may be formed by etching a portion of the substrate 100 (or by etching the epitaxial layer grown from the substrate 100) to define the first fin-type active pattern BP1 and the second fin-type active pattern BP2, and the field insulating film 105 may fill the fin trench.

The field insulating film 105 may be on the substrate 100 between the first fin-type active pattern BP1 and the second fin-type active pattern BP2. The field insulating film 105 may be in contact with the first fin-type active pattern BP1 and the second fin-type active pattern BP2. In some embodiments, the field insulating film 105 may cover the whole sidewall of the first fin-type active pattern BP1 and the whole sidewall of the second fin-type active pattern BP2.

In some embodiments, the field insulating film 105 may cover a portion of the sidewall of the first fin-type active pattern BP1 and/or a portion of the sidewall of the second fin-type active pattern BP2. For example, a portion of the first fin-type active pattern BP1 and/or a portion of the second fin-type active pattern BP2 may protrude from a top surface 105US of the field insulating film 105 in the vertical direction (the Z direction). The field insulating film 105 may not cover either the top surface of the first fin-type active pattern BP1 or the top surface of the second fin-type active pattern BP2. The first sheet-type active patterns NS1 and the second sheet-type active patterns NS2 may be positioned higher than the top surface 105US of the field insulating film 105.

The field insulating film 105 may include an insulating material such as an oxide film, a nitride film, an oxynitride film, or a combination thereof. The field insulating film 105 is depicted as single film but example embodiments are not limited thereto. The field insulating film 105 may include a field liner, which extends along the sidewall and bottom surface of a fin trench, and a field filling film on the field liner.

A plurality of gate structures GS may be arranged above the top surface 100US of the substrate 100. The gate structures GS may extend in the second horizontal direction (the Y direction). The gate structures GS may be spaced apart from each other in the first horizontal direction (the X direction). The gate structures GS may be adjacent to each other in the first horizontal direction (the X direction).

Each of the gate structures GS may be arranged on the first active pattern AP1 and the second active pattern AP2. Each gate structures GS may cross the first active pattern AP1 and the second active pattern AP2. The gate structure GS may cross the first fin-type active pattern BP1 and the second fin-type active pattern BP2. The gate structure GS may surround the first sheet-type active patterns NS1. The gate structure GS may surround the second sheet-type active pattern NS2.

The gate structure GS may include a gate electrode 120, a gate insulating film 130, a gate spacer 140, and a gate capping pattern 145. The gate structure GS may include a plurality of inner gate structures I_GS respectively between two first sheet-type active patterns NS1 adjacent to each other in the vertical direction (the Z direction) and between the first fin-type active pattern BP1 and one of the first sheet-type active patterns NS1.

The inner gate structures I_GS may be respectively between the top surface of the first fin-type active pattern BP1 and the bottom surface NS1_BS of the first sheet-type active pattern NS1 and between the top surface NS1_US of one of two first sheet-type active patterns NS1 facing each other in the vertical direction (the Z direction) and the bottom surface NS1_BS of the other first sheet-type active pattern NS1.

The number of inner gate structures I_GS may be the same as the number of first sheet-type active patterns NS1. The inner gate structures I_GS may be respectively in contact with a top surface BP1_US of the first fin-type active pattern BP1, the top surface NS1_US of a first sheet-type active pattern NS1, and the bottom surface NS1_BS of another first sheet-type active pattern NS1. In some embodiments, the inner gate structures I_GS may be in contact with the first and second source/drain patterns 150 and 160 described below.

Each of the inner gate structures I_GS may include the gate electrode 120 and a gate insulating film 130, which are between two adjacent first sheet-type active patterns NS1 or between the first fin-type active pattern BP1 and one of the first sheet-type active patterns NS1. Each of the inner gate structures I_GS may be between two second sheet-type active patterns NS2 adjacent to each other in the vertical direction (the Z direction) or between the second fin-type active pattern BP2 and one of the second sheet-type active patterns NS2. A width in the first horizontal direction (the X direction) of the gate electrode 120 may be less than a width in the first horizontal direction (the X direction) of each of the inner gate structures I_G2, but example embodiments are not limited thereto.

The gate electrode 120 may be arranged on the first fin-type active pattern BP1. The gate electrode 120 may cross the first fin-type active pattern BP1. The gate electrode 120 may surround the first sheet-type active patterns NS1. Although it is illustrated in FIG. 2 that a top surface 120US of the gate electrode 120 is a concave curved surface, embodiments are not limited thereto. The top surface 120US of the gate electrode 120 may be flat.

The gate electrode 120 may include at least one selected from the group consisting of metal, a metal alloy, conductive metal nitride, metal silicide, a doped semiconductor material, conductive metal oxide, and conductive metal oxynitride.

The gate electrode 120 may include, but not limited to, at least one selected from the group consisting of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof. Conductive metal oxide and conductive metal oxynitride may include, but not limited to, an oxidized form of the materials mentioned above. A material of the inner gate structures I_GS may be the same as a material of the gate electrode 120, but example embodiments are not limited thereto. For example, in some embodiments, the gate electrode 120 and inner gate structures I_GS may each include multi-layer structures and a number of the layers in the inner gate structures I_GS may be less than or equal to the number of the layers in the gate electrode 120. In other words, in some embodiments, one of the layers in the gate electrode 120 may be omitted in the inner gate structures I_GS, but example embodiments are not limited thereto.

The gate insulating film 130 may extend along the top surface 105US of the field insulating film 105, the top surface of the first fin-type active pattern BP1, and the top surface of the second fin-type active pattern BP2. The gate insulating film 130 may surround the first sheet-type active patterns NS1. The gate insulating film 130 may surround the second sheet-type active patterns NS2. The gate insulating film 130 may be arranged along the perimeters of the first sheet-type active patterns NS1 and the perimeters of the second sheet-type active patterns NS2. The gate electrode 120 may be disposed on the gate insulating film 130.

The gate insulating film 130 may be between the gate electrode 120 and each of the first sheet-type active patterns NS1 and between the gate electrode 120 and each of the second sheet-type active patterns NS2. In some embodiments, the gate insulating film 130 included in the inner gate structure I_GS may be in contact with the first and second source/drain patterns 150 and 160.

The gate insulating film 130 may include a dielectric material such as silicon oxide, silicon oxynitride, silicon nitride, or a high-permittivity material having a greater dielectric constant than silicon oxide. The high-permittivity material may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. The gate insulating film 130 is depicted as a single film but is not limited thereto. The gate insulating film 130 may include a plurality of films.

The gate spacer 140 may be arranged on the sidewall of the gate electrode 120. The g ate spacer 140 may not be arranged between the first fin-type active pattern BP1 and one of the first sheet-type active patterns NS1 and between two first sheet-type active patterns NS1 adjacent to each other in the vertical direction (the Z direction).

The gate spacer 140 may include at least one selected from the group consisting of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof. The gate spacer 140 is depicted as a single film but is not limited thereto.

The gate capping pattern 145 may be arranged on the gate electrode 120. A top surface 145US of the gate capping pattern 145 may be coplanar with the top surface of a first interlayer insulating film 190. The gate capping pattern 145 may include at least one selected from the group consisting of silicon nitride (SiN), silicon oxynitride (SiON), silicon carbonitride (SiCN), silicon oxycarbonitride (SiOCN), and a combination thereof. The gate capping pattern 145 may include a material having an etch selectivity with respect to the first interlayer insulating film 190.

The first source/drain pattern 150 may be arranged on the first active pattern AP1. The first source/drain pattern 150 may be arranged on the first fin-type active pattern BP1. The first source/drain pattern 150 may be between two gate electrodes 120 adjacent to each other in the first horizontal direction (the X direction). The first source/drain pattern 150 may be in contact with the first active pattern AP1.

The first source/drain pattern 150 may be in contact with the first sheet-type active patterns NS1. The first source/drain pattern 150 may be above the top surface 100US of the substrate 100 and connected to the first sheet-type active patterns NS1. The first source/drain pattern 150 may be connected to the first end NS1_E1 of each of the first sheet-type active patterns NS1.

The second source/drain pattern 160 may be arranged on the first active pattern AP1. The second source/drain pattern 160 may be arranged on the first fin-type active pattern BP1. The gate electrode 120 may be between the first source/drain pattern 150 and the second source/drain pattern 160.

The second source/drain pattern 160 may be between two gate electrodes 120 adjacent to each other in the first horizontal direction (the X direction). The second source/drain pattern 160 may be in contact with the first active pattern AP1. The second source/drain pattern 160 may be in contact with the first sheet-type active patterns NS1. The second source/drain pattern 160 may be above the top surface 100US of the substrate 100 and connected to the first sheet-type active patterns NS1. The second source/drain pattern 160 may be connected to the second end NS1_E2 of each of the first sheet-type active patterns NS1.

The first source/drain pattern 150 may include an upper source/drain region 150UR and a lower source/drain region 150LR. The upper source/drain region 150UR may be directly connected to the lower source/drain region 150LR. On the basis of the top surface 100US of the substrate 100, the upper source/drain region 150UR may be on the lower source/drain region 150LR.

The upper source/drain region 150UR may be in contact with the first sheet-type active patterns NS1. The lower source/drain region 150LR may not be in contact with the first sheet-type active patterns NS1.

The upper source/drain region 150UR may include a first cylindrical epitaxial region 151 and a first upper epitaxial region 152. In an example, the first cylindrical epitaxial region 151 may be on the first fin-type active pattern BP1. The first cylindrical epitaxial region 151 may be in contact with the first sheet-type active patterns NS1 and the first fin-type active pattern BP1.

In the cross-sectional view of FIG. 2, the first cylindrical epitaxial region 151 may be divided into two portions by the lower source/drain region 150LR. The first cylindrical epitaxial region 151 may have a shape similar to a line extending in the vertical direction (the Z direction).

The first upper epitaxial region 152 may be inside the first cylindrical epitaxial region 151. The first upper epitaxial region 152 may be in contact with the first cylindrical epitaxial region 151. The first cylindrical epitaxial region 151 may be between the first upper epitaxial region 152 and the first sheet-type active patterns NS1.

The upper source/drain region 150UR may include an epitaxial recess 150R_EP. In the cross-sectional views of FIGS. 2 and 4, the epitaxial recess 150R_EP may have an oval shape. In the cross-sectional view of FIG. 2, the epitaxial recess 150R_EP may be inside the first cylindrical epitaxial region 151 and inside the first upper epitaxial region 152. In the cross-sectional view of FIG. 4, the epitaxial recess 150R_EP may be inside the first upper epitaxial region 152.

The first upper epitaxial region 152 may include the epitaxial recess 150R_EP. The epitaxial recess 150R_EP may be arranged in a direction from the bottom surface 100BS of the substrate 100 to the top surface 100US of the substrate 100. The epitaxial recess 150R_EP may be inwardly recessed from the surface of the first fin-type active pattern BP1. The epitaxial recess 150R_EP may be arranged inside the first cylindrical epitaxial region 151 and recessed inwardly from the surface of the first fin-type active pattern BP1.

The lower source/drain region 150LR may be arranged in the epitaxial recess 150R_EP. The lower source/drain region 150LR may include a lower epitaxial region 153. The lower epitaxial region 153 may be arranged along the inner wall of the epitaxial recess 150R_EP.

The lower epitaxial region 153 may be formed along the inner wall of the epitaxial recess 150R_EP by a selective epitaxial growth method. The lower epitaxial region 153 may be in contact with the first cylindrical epitaxial region 151 and the first upper epitaxial region 152. In some embodiments, in the cross-sectional views of FIGS. 2 and 4, the lower epitaxial region 153 may have an oval shape.

The second source/drain pattern 160 may include a second cylindrical epitaxial region 161 and a second upper epitaxial region 162. The second upper epitaxial region 162 may be arranged inside the second cylindrical epitaxial region 161. In an example, the second cylindrical epitaxial region 161 may be on the first fin-type active pattern BP1. The second cylindrical epitaxial region 161 may be in contact with the first sheet-type active patterns NS1 and the first fin-type active pattern BP1. Unlike FIG. 2, the second cylindrical epitaxial region 161 may be formed on the top surface of the first fin-type active pattern BP1, that is, the top surface of the first fin-type active pattern BP1 below the second source/drain contact 175.

In the cross-sectional view of FIG. 4, the outer shape of each of the first source/drain pattern 150 and the second source/drain pattern 160 is depicted as being similar to a hexagon but is not limited thereto. Unlike FIG. 4, the outer shape of each of the first source/drain pattern 150 and the second source/drain pattern 160 may be similar to a tetragon or a pentagon.

In the cross-sectional view taken along line D-D in FIG. 4, the second cylindrical epitaxial region 161 may not have a cylindrical shape but may be formed to be rounded upward on the top surface of the first fin-type active pattern BP1. In some embodiments, in the cross-sectional view taken along line D-D in FIG. 4, the second cylindrical epitaxial region 161 may not have a cylindrical shape but may be formed to be rounded downwards from the top surface of the first fin-type active pattern BP1.

In some embodiments, the first cylindrical epitaxial region 151, the first upper epitaxial region 152, the lower epitaxial region 153, the second cylindrical epitaxial region 161, and the second upper epitaxial region 162 may include a semiconductor material, such as silicon or germanium.

In some embodiments, the first cylindrical epitaxial region 151, the first upper epitaxial region 152, the lower epitaxial region 153, the second cylindrical epitaxial region 161, and the second upper epitaxial region 162 may include a binary compound, a ternary compound, or a compound obtained by doping the binary compound or the ternary compound with a Group IV element, wherein the binary compound and the ternary compound may each include at least two selected from the group consisting of carbon (C), silicon (Si), germanium (Ge), and tin (Sn).

In some embodiments, the first cylindrical epitaxial region 151, the first upper epitaxial region 152, the lower epitaxial region 153, the second cylindrical epitaxial region 161, and the second upper epitaxial region 162 may each include an epitaxial film including a semiconductor.

The first cylindrical epitaxial region 151 and the second cylindrical epitaxial region 161 may be formed in the same manufacturing process. The first cylindrical epitaxial region 151 and the second cylindrical epitaxial region 161 may include the same material. When the first cylindrical epitaxial region 151 and the second cylindrical epitaxial region 161 include a compound such as silicon germanium, the concentration of germanium in the first cylindrical epitaxial region 151 may be the same as the concentration of germanium in the second cylindrical epitaxial region 161.

In some embodiments, the first cylindrical epitaxial region 151, the second cylindrical epitaxial region 161, and the lower epitaxial region 153 may include the same material. When the first cylindrical epitaxial region 151, the second cylindrical epitaxial region 161, and the lower epitaxial region 153 include a compound such as silicon germanium, the concentration of germanium may be about 0 at % to about 30 at %.

The first upper epitaxial region 152 and the second upper epitaxial region 162 may be manufactured in the same manufacturing process. The first upper epitaxial region 152 and the second upper epitaxial region 162 may include the same material.

When the first upper epitaxial region 152 and the second upper epitaxial region 162 include a compound such as silicon germanium, the concentration of germanium in each of the first upper epitaxial region 152 and the second upper epitaxial region 162 may be about 30 at % to about 70 at % that is greater than the concentration of germanium in each of the first cylindrical epitaxial region 151, the second cylindrical epitaxial region 161, and the lower epitaxial region 153.

The first source/drain pattern 150 and the second source/drain pattern 160 may include a dopant with which a semiconductor material is doped. The first source/drain pattern 150 and the second source/drain pattern 160 may include a dopant of the same conductivity type. In some embodiments, the first source/drain pattern 150 and the second source/drain pattern 160 may include a p-type dopant. The p-type dopant may include at least one of boron (B) and gallium (Ga) but is not limited thereto.

In some embodiments, the first source/drain pattern 150 and the second source/drain pattern 160 may include an n-type dopant. The n-type dopant may include, but not limited to, at least one selected from phosphorus (P), arsenic (As), antimony (Sb), and bismuth (Bi).

The concentration of dopants in the first cylindrical epitaxial region 151 may be less than the concentration of dopants in each of the first upper epitaxial region 152 and the lower epitaxial region 153. The concentration of dopants in the second cylindrical epitaxial region 161 may be less than the concentration of dopants in the second upper epitaxial region 162.

Because the first cylindrical epitaxial region 151 and the second cylindrical epitaxial region 161 are formed in the same manufacturing process, the concentration of dopants in the first cylindrical epitaxial region 151 may be equal to the concentration of dopants in the second cylindrical epitaxial region 161. Because the first upper epitaxial region 152 and the second upper epitaxial region 162 are formed in the same manufacturing process, the concentration of dopants in the first upper epitaxial region 152 may be equal to the concentration of dopants in the second upper epitaxial region 162.

The first cylindrical epitaxial region 151, the first upper epitaxial region 152, and the lower epitaxial region 153 may be distinguished from one another by the material, composition, and dopant concentration of an epitaxial film, but embodiments are not limited thereto. According to growth conditions and environments for the lower epitaxial region 153, the boundary between the first upper epitaxial region 152 and the lower epitaxial region 153 may not be identified.

In some embodiments, in the cross-sectional view of FIG. 2, a distance H1 from the surface of the first fin-type active pattern BP1 to the topmost surface of the lower epitaxial region 153 may be less than or equal to a distance H2 from the topmost surface of the lower epitaxial region 153 to the top surface of the first upper epitaxial region 152.

In some embodiments, in the cross-sectional view of FIG. 4, a height H11 from the bottom surface 100BS of the substrate 100 to the topmost part of the lower epitaxial region 153 of the first source/drain pattern 150 may be greater than a height H12 from the bottom surface 100BS of the substrate 100 to the bottommost part of the second source/drain pattern 160.

A source/drain etch stop layer 185 may extend along the outer wall of the gate spacer 140, the profile of the first source/drain pattern 150, and the profile of the second source/drain pattern 160. The source/drain etch stop layer 185 may be arranged on the top surface 105US of the field insulating film 105.

The source/drain etch stop layer 185 may include a material that has an etch selectivity with respect to the first interlayer insulating film 190 described below. The source/drain etch stop layer 185 may include at least one selected from the group consisting of silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and a combination thereof.

The first interlayer insulating film 190 may be arranged above the top surface 100US of the substrate 100. The first interlayer insulating film 190 may be arranged on the first source/drain pattern 150 and the second source/drain pattern 160. The first interlayer insulating film 190 may not cover the top surface 145US of the gate capping pattern 145. For example, the top surface of the first interlayer insulating film 190 may be coplanar with the top surface 145US of the gate capping pattern 145.

The first interlayer insulating film 190 may include at least one selected from the group consisting of silicon oxide, silicon nitride, silicon oxynitride, and a low-permittivity material. The low-permittivity material may include, but not limited to, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoam such as spolypropylene oxide, carbon doped silicon oxide (CDO), organo silicate glass (OSG), SiLK, amorphous fluorinated carbon, silica aerogels, silica xerogels, mesoporous silica, or a combination thereof.

The first source/drain contact 170 may extend lengthwise in the vertical direction (the Z direction). The first source/drain contact 170 may be connected to the first source/drain pattern 150. The first source/drain contact 170 may be electrically connected to the first source/drain pattern 150. The first source/drain contact 170 may pass through the first fin-type active pattern BP1 and the substrate 100.

The first source/drain contact 170 may extend from the bottom surface 100BS of the substrate 100 to the first source/drain pattern 150. A portion of the first source/drain contact 170 may be inside the substrate 100. The first source/drain contact 170 may be arranged in the epitaxial recess 150R_EP and in a power contact hole 170t, which passes through the substrate 100 and the first fin-type active pattern BP1. In the cross-sectional views of FIGS. 2 and 4, an upper portion of the first source/drain contact 170 may have an oval shape.

A depth from the top surface AP1_US of the first active pattern AP1 to a bottom surface 170BS of the first source/drain contact 170 may be equal to a depth from the top surface AP1_US of the first active pattern AP1 to the bottom surface 100BS of the substrate 100. The first source/drain contact 170 may include a sidewall 170SW extending from the bottom surface 100BS of the substrate 100 in the vertical direction (the Z direction).

The second source/drain contact 175 may extend lengthwise in the vertical direction (the Z direction). The second source/drain contact 175 may be electrically connected to the second source/drain pattern 160. The second source/drain contact 175 may be arranged above the top surface 100US of the substrate 100. The second source/drain contact 175 may not pass through the substrate 100.

A height from the top surface AP1_US of the first active pattern AP1 to a top surface 175US of the second source/drain contact 175 may be equal to a height from the top surface AP1_US of the first active pattern AP1 to the top surface 145US of the gate capping pattern 145.

A first contact silicide film 155 may be between the first source/drain contact 170 and the first source/drain pattern 150. The first contact silicide film 155 may be connected to the lower source/drain region 150LR. The first contact silicide film 155 may be in contact with the lower epitaxial region 153.

The first contact silicide film 155 may be arranged between the first source/drain contact 170 and the first source/drain pattern 150 and on the inner wall of the power contact hole 170t. The first contact silicide film 155 may be continuously arranged along the inner wall of the epitaxial recess 150R_EP and the inner wall of the power contact hole 170t.

The first contact silicide film 155 may be in contact with the lower epitaxial region 153 arranged along the inner wall of the epitaxial recess 150R_EP. In the cross-sectional views of FIGS. 2 and 4, an upper portion of the first contact silicide film 155 may have an oval shape.

A second contact silicide film 165 may be between the second source/drain contact 175 and the second source/drain pattern 160. The second contact silicide film 165 may be in contact with the second upper epitaxial region 162.

The first source/drain contact 170 may have a single-film structure. The first source/drain contact 170 may not have a multi-film structure including different materials. The first source/drain contact 170 may include a single conductive material. The first source/drain contact 170 may have a single-conductive film structure.

The first source/drain contact 170 may include metal that may selectively grow on a conductive material. The first source/drain contact 170 may include, but not limited to, titanium (Ti), tungsten (W), molybdenum (Mo), ruthenium (Ru), or cobalt (Co). The second source/drain contact 175 is depicted as having a single-conductive film structure but is not limited thereto.

The second source/drain contact 175 may include at least one selected from the group consisting of metal, a metal alloy, conductive metal nitride, conductive metal carbide, conductive metal oxide, conductive metal carbonitride, and a two-dimensional (2D) material.

The first contact silicide film 155 and the second contact silicide film 165 may include a metal silicide material. The first contact silicide film 155 may reduce resistance between the first source/drain contact 170 and the first source/drain pattern 150. Accordingly, the performance and reliability of a semiconductor device may be increased. The first power line 50 may be arranged on the bottom surface 100BS of the substrate 100.

The first power line 50 may be connected to the first source/drain contact 170. The first source/drain contact 170 may connect the first power line 50 to the first source/drain pattern 150. The second source/drain contact 175 may not be connected to the first power line 50. The first power line 50 may include at least one selected from the group consisting of metal, a metal alloy, conductive metal nitride, conductive metal carbide, conductive metal oxide, conductive metal carbonitride, and a 2D material.

A second interlayer insulating film 191 may be arranged on the first interlayer insulating film 190, the gate structure GS, and the second source/drain contact 175. The second interlayer insulating film 191 may include at least one selected from the group consisting of silicon oxide, silicon nitride, silicon carbonitride, silicon oxynitride, and a low-permittivity material.

A wiring structure 195 may be arranged inside the second interlayer insulating film 191. The wiring structure 195 may be arranged above the top surface 100US of the substrate 100. The wiring structure 195 may include a via plug 196 and a wiring line 197.

The wiring structure 195 may be connected to the second source/drain contact 175. The second source/drain contact 175 may connect the wiring structure 195 to the second source/drain pattern 160. The wiring structure 195 may not be connected to the first source/drain contact 170.

The via plug 196 and the wiring line 197 may each include at least one selected from the group consisting of metal, a metal alloy, conductive metal nitride, conductive metal carbide, conductive metal oxide, conductive metal carbonitride, and a 2D material. The via plug 196 and the wiring line 197 are each depicted as having a single-conductive film structure, but this is just for convenience of description. Embodiments are not limited thereto.

As described above, the semiconductor device EX1 may include the first source/drain pattern 150, which includes the lower epitaxial region 153 and the first upper epitaxial region 152. The first upper epitaxial region 152 may include the epitaxial recess 150R_EP that is recessed inwardly from the surface of the first fin-type active pattern BP1, and the lower epitaxial region 153 may be arranged along the inner wall of the epitaxial recess 150R_EP.

The semiconductor device EX1 may prevent loss of a dopant, which is included in the first source/drain pattern 150, due to the lower epitaxial region 153. Accordingly, the semiconductor device EX1 may reduce contact resistance between the first source/drain pattern 150 and the first source/drain contact 170, thereby improving electrical characteristics and device reliability.

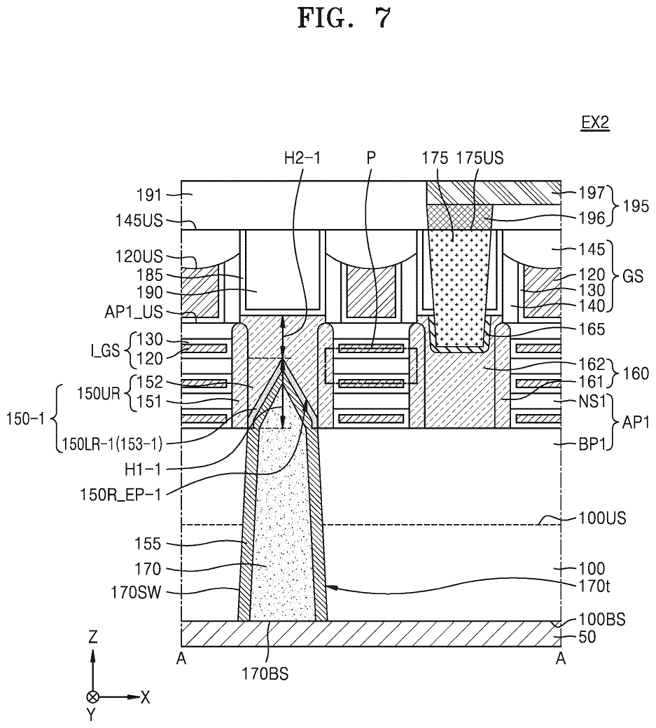

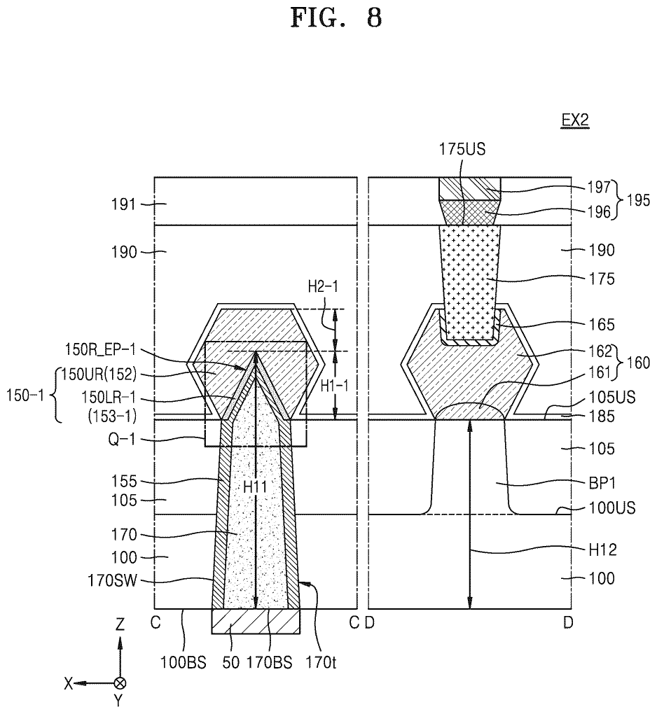

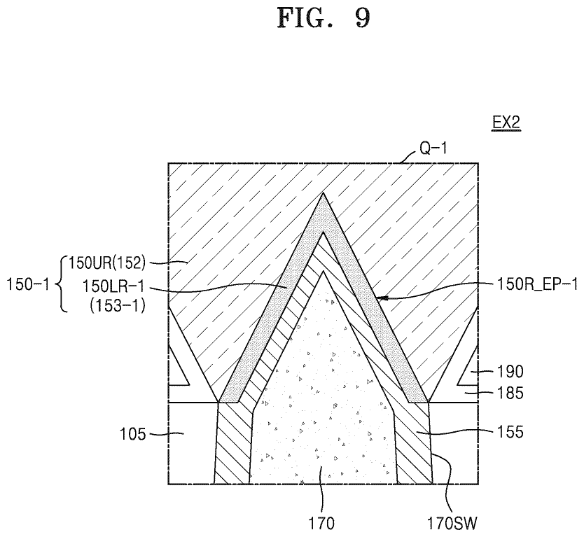

FIGS. 7 and 8 are cross-sectional views of a semiconductor device according to an embodiment. FIG. 9 is an enlarged view of a region Q-1 in FIG. 8.

In an embodiment, a semiconductor device EX2 may be nearly the same as the semiconductor device EX1 of FIGS. 1 to 6, except for the shape of an epitaxial recess 150R_EP-1 and the shape of a lower epitaxial region 153-1. In FIGS. 1 to 9, like reference numerals denote like elements. Redundant descriptions given above with reference to FIGS. 1 to 6 are brief or omitted below.

The semiconductor device EX2 may include the first active pattern AP1, a plurality of gate electrodes 120, a first source/drain pattern 150-1, the second source/drain pattern 160, the first source/drain contact 170, and the second source/drain contact 175.

The first source/drain pattern 150-1 may include the upper source/drain region 150UR and a lower source/drain region 150LR-1. The upper source/drain region 150UR may be directly connected to the lower source/drain region 150LR-1. On the basis of the top surface 100US of the substrate 100, the upper source/drain region 150UR may be on the lower source/drain region 150LR-1.

The upper source/drain region 150UR may be in contact with the first sheet-type active patterns NS1. The lower source/drain region 150LR-1 may not be in contact with the first sheet-type active patterns NS1.

The upper source/drain region 150UR may include the first cylindrical epitaxial region 151 and the first upper epitaxial region 152. The first cylindrical epitaxial region 151 may be in contact with the first sheet-type active patterns NS1 and the first fin-type active pattern BP1.

In the cross-sectional view of FIG. 7, the first cylindrical epitaxial region 151 may be divided into two portions by the lower source/drain region 150LR-1. The first cylindrical epitaxial region 151 may have a shape similar to a line extending in the vertical direction (the Z direction).

The first upper epitaxial region 152 may be inside the first cylindrical epitaxial region 151. The first upper epitaxial region 152 may be in contact with the first cylindrical epitaxial region 151. The first cylindrical epitaxial region 151 may be between the first upper epitaxial region 152 and the first sheet-type active patterns NS1.

The upper source/drain region 150UR may include the epitaxial recess 150R_EP-1. In the cross-sectional view of FIG. 7, the epitaxial recess 150R_EP-1 may be inside the first cylindrical epitaxial region 151 and inside the first upper epitaxial region 152. In the cross-sectional view of FIG. 8, the epitaxial recess 150R_EP-1 may be inside the first upper epitaxial region 152.

The first upper epitaxial region 152 may include the epitaxial recess 150R_EP-1. In some embodiments, in the cross-sectional views of FIGS. 7 and 8, the epitaxial recess 150R_EP-1 may have a triangular shape. The epitaxial recess 150R_EP-1 may be arranged in a direction from the bottom surface 100BS of the substrate 100 to the top surface 100US of the substrate 100. The epitaxial recess 150R_EP-1 may be inwardly recessed from the surface of the first fin-type active pattern BP1 (e.g., toward the inside of the first source/drain pattern 150-1 (alternatively, the first cylindrical epitaxial region 151 and/or the first upper epitaxial region 152)). The epitaxial recess 150R_EP-1 may be arranged inside the first cylindrical epitaxial region 151 and recessed inwardly from the surface of the first fin-type active pattern BP1.

The lower source/drain region 150LR-1 may be arranged in the epitaxial recess 150R_EP-1. The lower source/drain region 150LR-1 may include a lower epitaxial region 153-1. The lower epitaxial region 153-1 may be arranged along the inner wall of the epitaxial recess 150R_EP-1. In some embodiments, a portion of the lower epitaxial region 153-1 may be arranged on the inner wall of the first cylindrical epitaxial region 151.

The lower epitaxial region 153-1 may be formed along the inner wall of the epitaxial recess 150R_EP-1 by a selective epitaxial growth method. The lower epitaxial region 153-1 may be in contact with the first cylindrical epitaxial region 151 and the first upper epitaxial region 152. In some embodiments, in the cross-sectional views of FIGS. 7 and 8, the lower epitaxial region 153-1 may have a triangular shape.

In some embodiments, in the cross-sectional views of FIGS. 7 and 8, a distance H1-1 from the surface of the first fin-type active pattern BP1 to the topmost surface of the lower epitaxial region 153-1 may be greater than a distance H2-1 from the topmost surface of the lower epitaxial region 153-1 to the top surface of the first upper epitaxial region 152.

In some embodiments, unlike FIGS. 7 and 8, the distance H1-1 from the surface of the first fin-type active pattern BP1 to the topmost surface of the lower epitaxial region 153-1 may be less than or equal to the distance H2-1 from the topmost surface of the lower epitaxial region 153-1 to the top surface of the first upper epitaxial region 152.

In some embodiments, in the cross-sectional view of FIG. 8, the height H11 from the bottom surface 100BS of the substrate 100 to the topmost part of the lower epitaxial region 153-1 of the first source/drain pattern 150-1 may be greater than the height H12 from the bottom surface 100BS of the substrate 100 to the bottommost part of the second source/drain pattern 160.

The semiconductor device EX2 may include the first source/drain contact 170, the first contact silicide film 155, and the second source/drain contact 175. The first source/drain contact 170 may extend lengthwise in the vertical direction (the Z direction). The first source/drain contact 170 may be electrically connected to the first source/drain pattern 150-1. The first source/drain contact 170 may pass through the first fin-type active pattern BP1 and the substrate 100.

The first source/drain contact 170 may extend from the bottom surface 100BS of the substrate 100 to the first source/drain pattern 150-1. A portion of the first source/drain contact 170 may be inside the substrate 100. The first source/drain contact 170 may be arranged in the epitaxial recess 150R_EP-1 and in the power contact hole 170t, which passes through the substrate 100 and the first fin-type active pattern BP1.

In the cross-sectional views of FIGS. 7 and 8, an upper portion of the first source/drain contact 170 may have a triangular shape. The first source/drain contact 170 may include the sidewall 170SW extending from the bottom surface 100BS of the substrate 100 in the vertical direction (the Z direction).

The second source/drain contact 175 may extend lengthwise in the vertical direction (the Z direction). The second source/drain contact 175 may be electrically connected to the second source/drain pattern 160. The second source/drain contact 175 may be arranged above the top surface 100US of the substrate 100. The second source/drain contact 175 may not pass through the substrate 100.

The first contact silicide film 155 may be between the first source/drain contact 170 and the first source/drain pattern 150-1. The first contact silicide film 155 may be connected to the lower source/drain region 150LR-1. The first contact silicide film 155 may be in contact with the lower epitaxial region 153-1.

The first contact silicide film 155 may be arranged between the first source/drain contact 170 and the first source/drain pattern 150-1 and on the inner wall of the power contact hole 170t. The first contact silicide film 155 may be continuously arranged along the inner wall of the epitaxial recess 150R_EP-1 and the inner wall of the power contact hole 170t.

The first contact silicide film 155 may be in contact with the lower epitaxial region 153-1 arranged along the inner wall of the epitaxial recess 150R_EP-1. In the cross-sectional views of FIGS. 7 and 8, the upper portion of the first contact silicide film 155 may have a triangular shape.

The second contact silicide film 165 may be between the second source/drain contact 175 and the second source/drain pattern 160. The second contact silicide film 165 may be in contact with the second upper epitaxial region 162.

The semiconductor device EX2 may include the first power line 50, the first interlayer insulating film 190, the second interlayer insulating film 191, and the wiring structure 195. The first power line 50 may be connected to the first source/drain contact 170. The first source/drain contact 170 may connect the first power line 50 to the first source/drain pattern 150-1.

The wiring structure 195 may be arranged inside the second interlayer insulating film 191. The wiring structure 195 may be arranged above the top surface 100US of the substrate 100. The wiring structure 195 may include the via plug 196 and the wiring line 197. The wiring structure 195 may be connected to the second source/drain contact 175. The second source/drain contact 175 may electrically connect the wiring structure 195 to the second source/drain pattern 160.

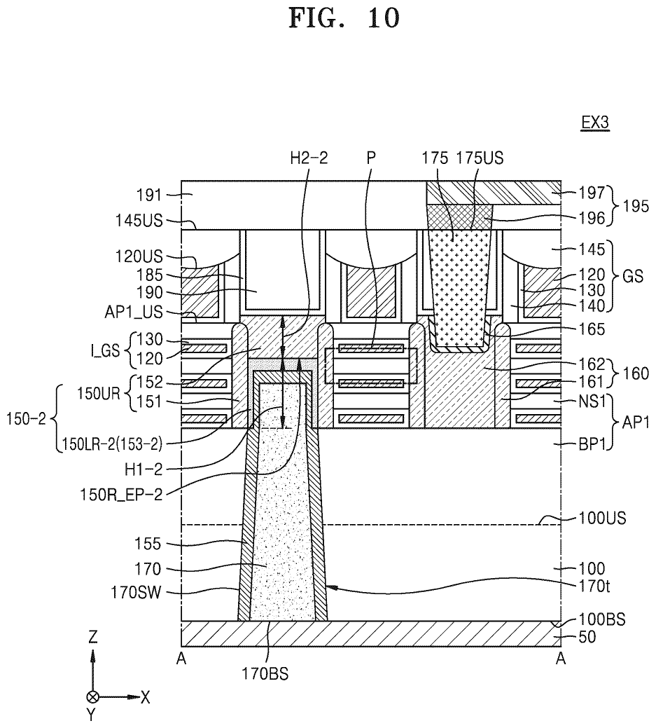

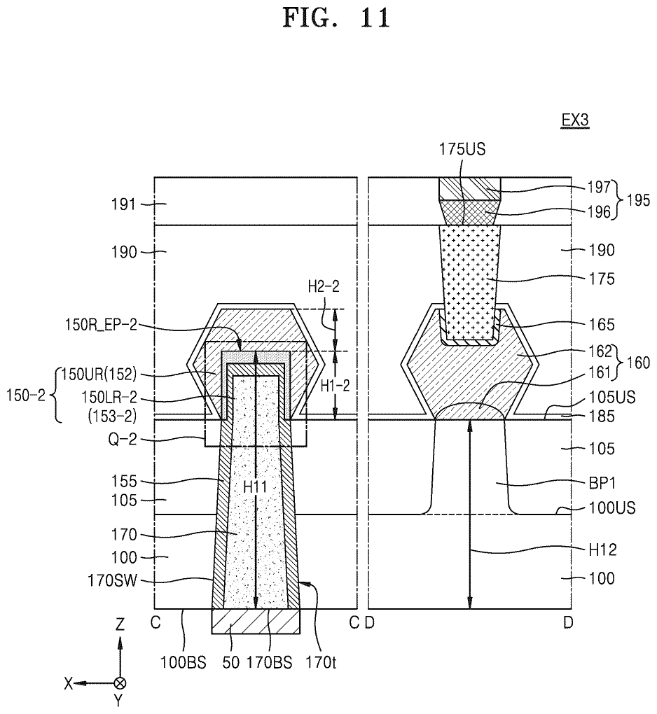

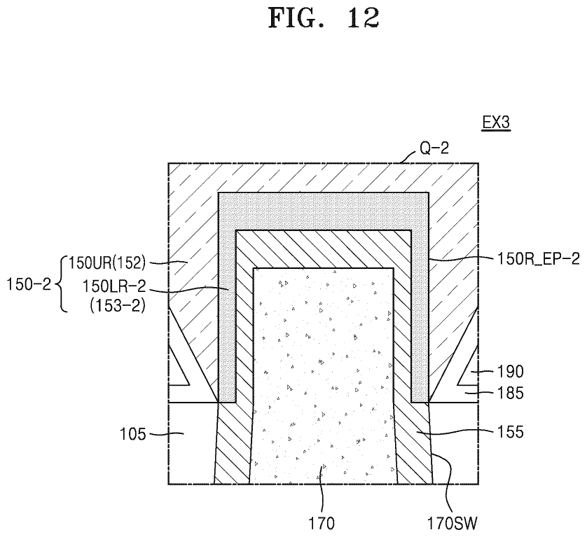

FIGS. 10 and 11 are cross-sectional views of a semiconductor device according to an embodiment. FIG. 12 is an enlarged view of a region Q-2 in FIG. 11.

In an embodiment, a semiconductor device EX3 may be nearly the same as the semiconductor device EX1 of FIGS. 1 to 6, except for the shape of an epitaxial recess 150R_EP-2 and the shape of a lower epitaxial region 153-2. In FIGS. 1 to 6 and FIGS. 10 to 12, like reference numerals denote like elements. Redundant descriptions given above with reference to FIGS. 1 to 6 are brief or omitted below.

The semiconductor device EX3 may include the first active pattern AP1, the gate electrodes 120, a first source/drain pattern 150-2, the second source/drain pattern 160, the first source/drain contact 170, and the second source/drain contact 175.

The first source/drain pattern 150-2 may include the upper source/drain region 150UR and a lower source/drain region 150LR-2. The upper source/drain region 150UR may be directly connected to the lower source/drain region 150LR-2. On the basis of the top surface 100US of the substrate 100, the upper source/drain region 150UR may be on the lower source/drain region 150LR-2.

The upper source/drain region 150UR may be in contact with the first sheet-type active patterns NS1. The lower source/drain region 150LR-2 may not be in contact with the first sheet-type active patterns NS1.

The upper source/drain region 150UR may include the first cylindrical epitaxial region 151 and the first upper epitaxial region 152. The first cylindrical epitaxial region 151 may be in contact with the first sheet-type active patterns NS1 and the first fin-type active pattern BP1.

In the cross-sectional view of FIG. 10, the first cylindrical epitaxial region 151 may be divided into two portions by the lower source/drain region 150LR-2. The first cylindrical epitaxial region 151 may have a shape similar to a line extending in the vertical direction (the Z direction).

The first upper epitaxial region 152 may be inside the first cylindrical epitaxial region 151. The first upper epitaxial region 152 may be in contact with the first cylindrical epitaxial region 151. The first cylindrical epitaxial region 151 may be between the first upper epitaxial region 152 and the first sheet-type active patterns NS1.

The upper source/drain region 150UR may include the epitaxial recess 150R_EP-2. In the cross-sectional view of FIG. 10, the epitaxial recess 150R_EP-2 may be inside the first cylindrical epitaxial region 151 and inside the first upper epitaxial region 152. In the cross-sectional view of FIG. 10, the epitaxial recess 150R_EP-2 may be inside the first upper epitaxial region 152.

The first upper epitaxial region 152 may include the epitaxial recess 150R_EP-2. In some embodiments, in the cross-sectional views of FIGS. 10 and 11, the epitaxial recess 150R_EP-2 may have an inverted U-shape. The epitaxial recess 150R_EP-2 may be arranged in a direction from the bottom surface 100BS of the substrate 100 to the top surface 100US of the substrate 100. The epitaxial recess 150R_EP-2 may be inwardly recessed from the surface of the first fin-type active pattern BP1. The epitaxial recess 150R_EP-2 may be arranged inside the first cylindrical epitaxial region 151 and recessed inwardly from the surface of the first fin-type active pattern BP1.

The lower source/drain region 150LR-2 may be arranged in the epitaxial recess 150R_EP-2. The lower source/drain region 150LR-2 may include a lower epitaxial region 153-2. The lower epitaxial region 153-2 may be arranged along the inner wall of the epitaxial recess 150R_EP-2. In some embodiments, a portion of the lower epitaxial region 153-2 may be arranged on the inner wall of the first cylindrical epitaxial region 151.

The lower epitaxial region 153-2 may be formed along the inner wall of the epitaxial recess 150R_EP-2 by a selective epitaxial growth method. The lower epitaxial region 153-2 may be in contact with the first cylindrical epitaxial region 151 and the first upper epitaxial region 152. In some embodiments, in the cross-sectional views of FIGS. 10 and 11, the lower epitaxial region 153-2 may have an inverted U-shape.

In some embodiments, in the cross-sectional views of FIGS. 10 and 11, a distance H1-2 from the surface of the first fin-type active pattern BP1 to the topmost surface of the lower epitaxial region 153-2 may be greater than a distance H2-2 from the topmost surface of the lower epitaxial region 153-2 to the top surface of the first upper epitaxial region 152.

In some embodiments, unlike FIGS. 10 and 11, the distance H1-2 from the surface of the first fin-type active pattern BP1 to the topmost surface of the lower epitaxial region 153-2 may be less than or equal to the distance H2-2 from the topmost surface of the lower epitaxial region 153-2 to the top surface of the first upper epitaxial region 152.

In some embodiments, in the cross-sectional view of FIG. 11, the height H11 from the bottom surface 100BS of the substrate 100 to the topmost part of the lower epitaxial region 153-2 of the first source/drain pattern 150-2 may be greater than the height H12 from the bottom surface 100BS of the substrate 100 to the bottommost part of the second source/drain pattern 160.

The semiconductor device EX3 may include the first source/drain contact 170, the first contact silicide film 155, and the second source/drain contact 175. The first source/drain contact 170 may extend lengthwise in the vertical direction (the Z direction). The first source/drain contact 170 may be electrically connected to the first source/drain pattern 150-2. The first source/drain contact 170 may pass through the first fin-type active pattern BP1 and the substrate 100.

The first source/drain contact 170 may extend from the bottom surface 100BS of the substrate 100 to the first source/drain pattern 150-2. A portion of the first source/drain contact 170 may be inside the substrate 100. The first source/drain contact 170 may be arranged in the epitaxial recess 150R_EP-2 and in the power contact hole 170t, which passes through the substrate 100 and the first fin-type active pattern BP1.

In the cross-sectional views of FIGS. 10 and 11, an upper portion of the first source/drain contact 170 may have an inverted U-shape. The first source/drain contact 170 may include the sidewall 170SW extending from the bottom surface 100BS of the substrate 100 in the vertical direction (the Z direction).

The second source/drain contact 175 may extend lengthwise in the vertical direction (the Z direction). The second source/drain contact 175 may be electrically connected to the second source/drain pattern 160. The second source/drain contact 175 may be arranged above the top surface 100US of the substrate 100. The second source/drain contact 175 may not pass through the substrate 100.

The first contact silicide film 155 may be between the first source/drain contact 170 and the first source/drain pattern 150-2. The first contact silicide film 155 may be connected to the lower source/drain region 150LR-2. The first contact silicide film 155 may be in contact with the lower epitaxial region 153-2.

The first contact silicide film 155 may be arranged between the first source/drain contact 170 and the first source/drain pattern 150-2 and on the inner wall of the power contact hole 170t. The first contact silicide film 155 may be continuously arranged along the inner wall of the epitaxial recess 150R_EP-2 and the inner wall of the power contact hole 170t.

The first contact silicide film 155 may be in contact with the lower epitaxial region 153-2 arranged along the inner wall of the epitaxial recess 150R_EP-2. In the cross-sectional views of FIGS. 10 and 11, the upper portion of the first contact silicide film 155 may have an inverted U-shape.

The second contact silicide film 165 may be between the second source/drain contact 175 and the second source/drain pattern 160. The second contact silicide film 165 may be in contact with the second upper epitaxial region 162.

The semiconductor device EX3 may include the first power line 50, the first interlayer insulating film 190, the second interlayer insulating film 191, and the wiring structure 195. The first power line 50 may be connected to the first source/drain contact 170. The first source/drain contact 170 may connect the first power line 50 to the first source/drain pattern 150-2.

The wiring structure 195 may be arranged inside the second interlayer insulating film 191. The wiring structure 195 may be arranged above the top surface 100US of the substrate 100. The wiring structure 195 may include the via plug 196 and the wiring line 197. The wiring structure 195 may be connected to the second source/drain contact 175. The second source/drain contact 175 may electrically connect the wiring structure 195 to the second source/drain pattern 160.

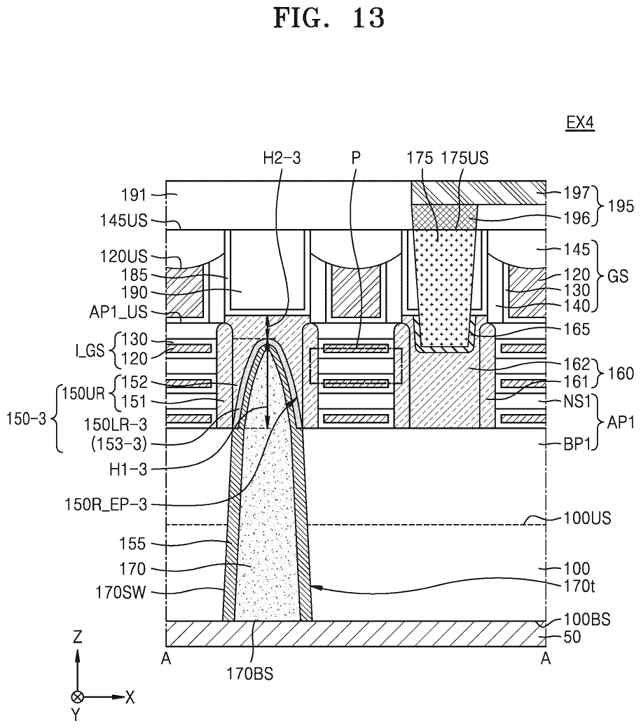

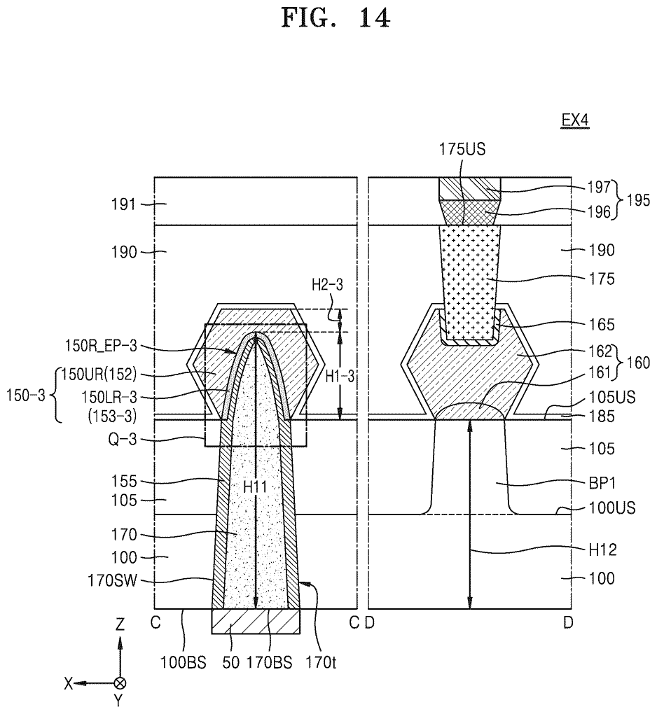

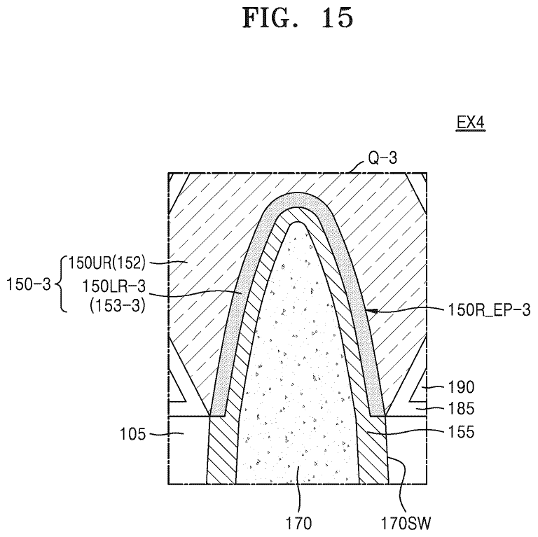

FIGS. 13 and 14 are cross-sectional views of a semiconductor device according to an embodiment. FIG. 15 is an enlarged view of a region Q-3 in FIG. 14.

In an embodiment, a semiconductor device EX4 may be nearly the same as the semiconductor device EX1 of FIGS. 1 to 6, except for the vertical height (or distance) of an epitaxial recess 150R_EP-3 and the vertical height (or distance) of a lower epitaxial region 153-3. In FIGS. 1 to 6 and FIGS. 13 to 15, like reference numerals denote like elements. Redundant descriptions given above with reference to FIGS. 1 to 6 are brief or omitted below.

A semiconductor device EX4 may include the first active pattern AP1, the gate electrodes 120, a first source/drain pattern 150-3, the second source/drain pattern 160, the first source/drain contact 170, and the second source/drain contact 175.

The first source/drain pattern 150-3 may include the upper source/drain region 150UR and a lower source/drain region 150LR-3. The upper source/drain region 150UR may be directly connected to the lower source/drain region 150LR-3. On the basis of the top surface 100US of the substrate 100, the upper source/drain region 150UR may be on the lower source/drain region 150LR-3.

The upper source/drain region 150UR may be in contact with the first sheet-type active patterns NS1. The lower source/drain region 150LR-3 may not be in contact with the first sheet-type active patterns NS1.

The upper source/drain region 150UR may include the first cylindrical epitaxial region 151 and the first upper epitaxial region 152. The first cylindrical epitaxial region 151 may be in contact with the first sheet-type active patterns NS1 and the first fin-type active pattern BP1.

In the cross-sectional view of FIG. 13, the first cylindrical epitaxial region 151 may be divided into two portions by the lower source/drain region 150LR-3. The first cylindrical epitaxial region 151 may have a shape similar to a line extending in the vertical direction (the Z direction).

The first upper epitaxial region 152 may be inside the first cylindrical epitaxial region 151. The first upper epitaxial region 152 may be in contact with the first cylindrical epitaxial region 151. The first cylindrical epitaxial region 151 may be between the first upper epitaxial region 152 and the first sheet-type active patterns NS1.

The upper source/drain region 150UR may include the epitaxial recess 150R_EP-3. In the cross-sectional view of FIG. 13, the epitaxial recess 150R_EP-3 may be inside the first cylindrical epitaxial region 151 and inside the first upper epitaxial region 152. In the cross-sectional view of FIG. 13, the epitaxial recess 150R_EP-3 may be inside the first upper epitaxial region 152.

The first upper epitaxial region 152 may include the epitaxial recess 150R_EP-3. In some embodiments, in the cross-sectional views of FIGS. 13 and 14, the epitaxial recess 150R_EP-3 may have an oval shape. The epitaxial recess 150R_EP-3 may be arranged in a direction from the bottom surface 100BS of the substrate 100 to the top surface 100US of the substrate 100. The epitaxial recess 150R_EP-3 may be inwardly recessed from the surface of the first fin-type active pattern BP1. The epitaxial recess 150R_EP-3 may be arranged inside the first cylindrical epitaxial region 151 and recessed inwardly from the surface of the first fin-type active pattern BP1.

The lower source/drain region 150LR-3 may be arranged in the epitaxial recess 150R_EP-3. The lower source/drain region 150LR-3 may include a lower epitaxial region 153-3. The lower epitaxial region 153-3 may be arranged along the inner wall of the epitaxial recess 150R_EP-3. In some embodiments, a portion of the lower epitaxial region 153-3 may be arranged on the inner wall of the first cylindrical epitaxial region 151.

The lower epitaxial region 153-3 may be formed along the inner wall of the epitaxial recess 150R_EP-3 by a selective epitaxial growth method. The lower epitaxial region 153-3 may be in contact with the first cylindrical epitaxial region 151 and the first upper epitaxial region 152. In some embodiments, in the cross-sectional views of FIGS. 13 and 14, the lower epitaxial region 153-3 may have an oval shape.

In some embodiments, in the cross-sectional view of FIG. 13, a distance H1-3 from the surface of the first fin-type active pattern BP1 to the topmost surface of the lower epitaxial region 153-3 may be greater than a distance H2-3 from the topmost surface of the lower epitaxial region 153-3 to the top surface of the first upper epitaxial region 152.

In some embodiments, in the cross-sectional view of FIG. 14, the height H11 from the bottom surface 100BS of the substrate 100 to the topmost part of the lower epitaxial region 153-3 of the first source/drain pattern 150-3 may be greater than the height H12 from the bottom surface 100BS of the substrate 100 to the bottommost part of the second source/drain pattern 160.

The semiconductor device EX4 may include the first source/drain contact 170, the first contact silicide film 155, and the second source/drain contact 175. The first source/drain contact 170 may extend lengthwise in the vertical direction (the Z direction). The first source/drain contact 170 may be electrically connected to the first source/drain pattern 150-3. The first source/drain contact 170 may pass through the first fin-type active pattern BP1 and the substrate 100.

The first source/drain contact 170 may extend from the bottom surface 100BS of the substrate 100 to the first source/drain pattern 150-3. A portion of the first source/drain contact 170 may be inside the substrate 100. The first source/drain contact 170 may be arranged in the epitaxial recess 150R_EP-3 and in the power contact hole 170t, which passes through the substrate 100 and the first fin-type active pattern BP1.

In the cross-sectional views of FIGS. 13 and 14, an upper portion of the first source/drain contact 170 may have an oval shape. The first source/drain contact 170 may include the sidewall 170SW extending from the bottom surface 100BS of the substrate 100 in the vertical direction (the Z direction).

The second source/drain contact 175 may extend lengthwise in the vertical direction (the Z direction). The second source/drain contact 175 may be electrically connected to the second source/drain pattern 160. The second source/drain contact 175 may be arranged above the top surface 100US of the substrate 100. The second source/drain contact 175 may not pass through the substrate 100.

The first contact silicide film 155 may be between the first source/drain contact 170 and the first source/drain pattern 150-3. The first contact silicide film 155 may be connected to the lower source/drain region 150LR-3. The first contact silicide film 155 may be in contact with the lower epitaxial region 153-3.

The first contact silicide film 155 may be arranged between the first source/drain contact 170 and the first source/drain pattern 150-3 and on the inner wall of the power contact hole 170t. The first contact silicide film 155 may be continuously arranged along the inner wall of the epitaxial recess 150R_EP-3 and the inner wall of the power contact hole 170t.

The first contact silicide film 155 may be in contact with the lower epitaxial region 153-3 arranged along the inner wall of the epitaxial recess 150R_EP-3. In the cross-sectional views of FIGS. 14 and 15, the upper portion of the first contact silicide film 155 may have an oval shape.

The second contact silicide film 165 may be between the second source/drain contact 175 and the second source/drain pattern 160. The second contact silicide film 165 may be in contact with the second upper epitaxial region 162.

The semiconductor device EX4 may include the first power line 50, the first interlayer insulating film 190, the second interlayer insulating film 191, and the wiring structure 195. The first power line 50 may be connected to the first source/drain contact 170. The first source/drain contact 170 may connect the first power line 50 to the first source/drain pattern 150-3.

The wiring structure 195 may be arranged inside the second interlayer insulating film 191. The wiring structure 195 may be arranged above the top surface 100US of the substrate 100. The wiring structure 195 may include the via plug 196 and the wiring line 197. The wiring structure 195 may be connected to the second source/drain contact 175. The second source/drain contact 175 may electrically connect the wiring structure 195 to the second source/drain pattern 160.

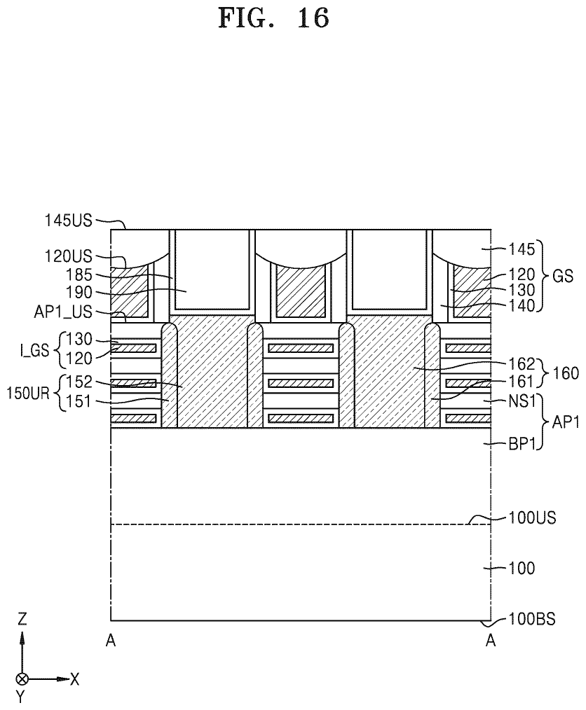

FIGS. 16 to 23 are cross-sectional views illustrating a method of manufacturing a semiconductor device, according to an embodiment.

FIGS. 16 to 23 may illustrate a method of manufacturing the semiconductor device EX1 of FIGS. 1 to 6. In FIGS. 1 to 6 and FIGS. 16 to 23, like reference numerals denote like elements. Redundant descriptions given above with reference to FIGS. 1 to 6 are brief or omitted below.

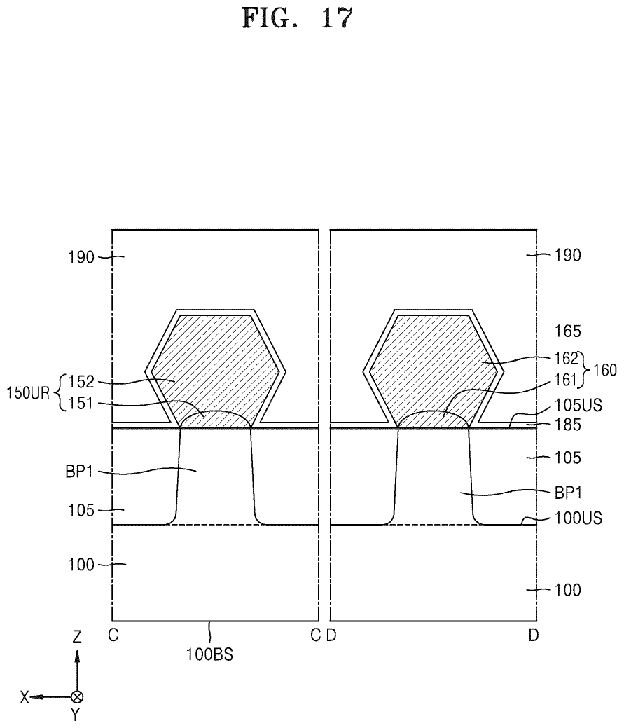

Referring to FIGS. 16 and 17, the upper source/drain region 150UR and the second source/drain pattern 160 may be formed on the first fin-type active pattern BP1. The upper source/drain region 150UR may include the first cylindrical epitaxial region 151 and the first upper epitaxial region 152.

The second source/drain pattern 160 may include the second cylindrical epitaxial region 161 and the second upper epitaxial region 162. The gate spacer 140 may be formed on the first fin-type active pattern BP1 before the upper source/drain region 150UR and the second source/drain pattern 160 are formed.

The source/drain etch stop layer 185 and the first interlayer insulating film 190 may be formed on the upper source/drain region 150UR and the second source/drain pattern 160. Subsequently, a first sheet-type active pattern NS1 may be formed on the first fin-type active pattern BP1. Accordingly, the first active pattern AP1 may be formed on the top surface 100US of the substrate 100.

Subsequently, a gate insulating film 130 and a gate electrode 120 may be formed on the first fin-type active pattern BP1 to surround the first sheet-type active pattern NS1. The gate capping pattern 145 may be formed on the gate electrode 120. Accordingly, a gate structure GS may be formed on the first active pattern AP1. The top surface 145US of the gate capping pattern 145 may be coplanar with the top surface of the first interlayer insulating film 190.

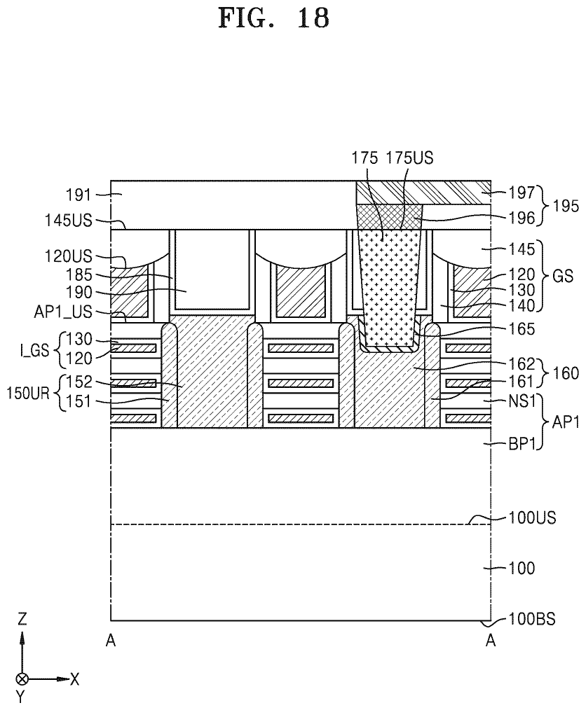

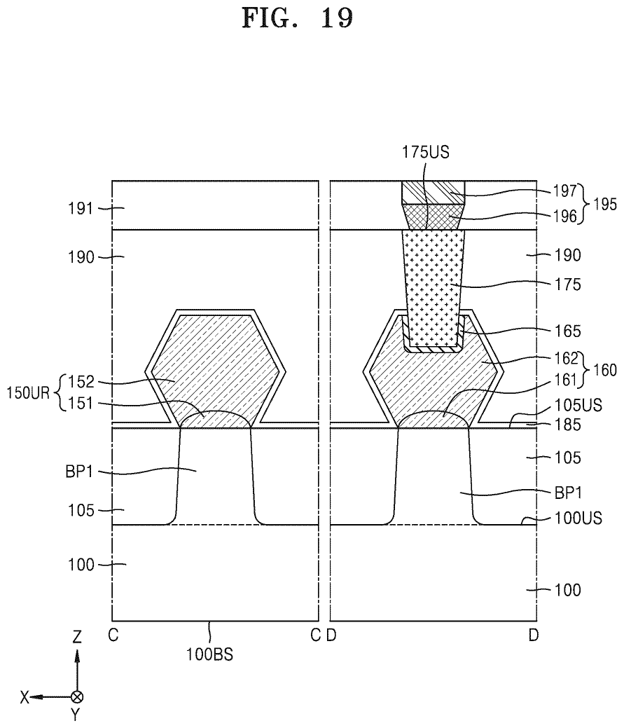

Referring to FIGS. 18 and 19, the second source/drain contact 175 may be formed above the top surface 100US of the substrate 100. The second source/drain contact 175 may be connected to the second source/drain pattern 160. Before the second source/drain contact 175 is formed, the second contact silicide film 165 may be formed on the second source/drain pattern 160.

Subsequently, the wiring structure 195 may be formed on the gate structure GS and the second source/drain contact 175. The wiring structure 195 may be connected to the second source/drain contact 175.

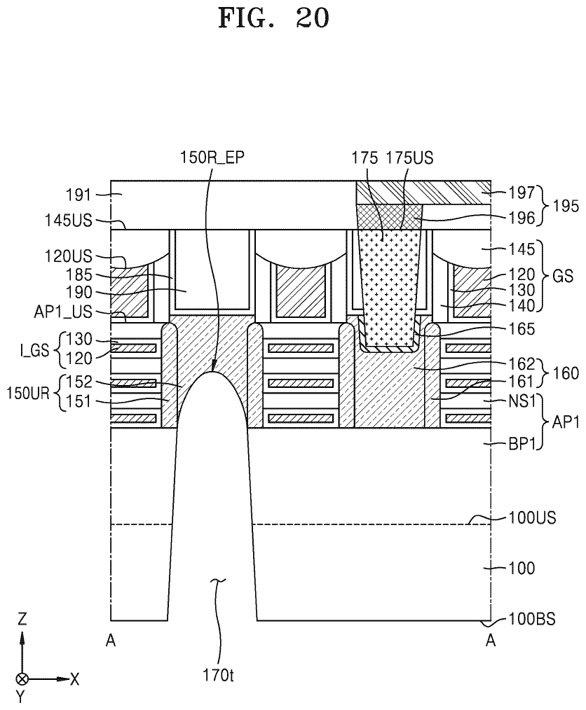

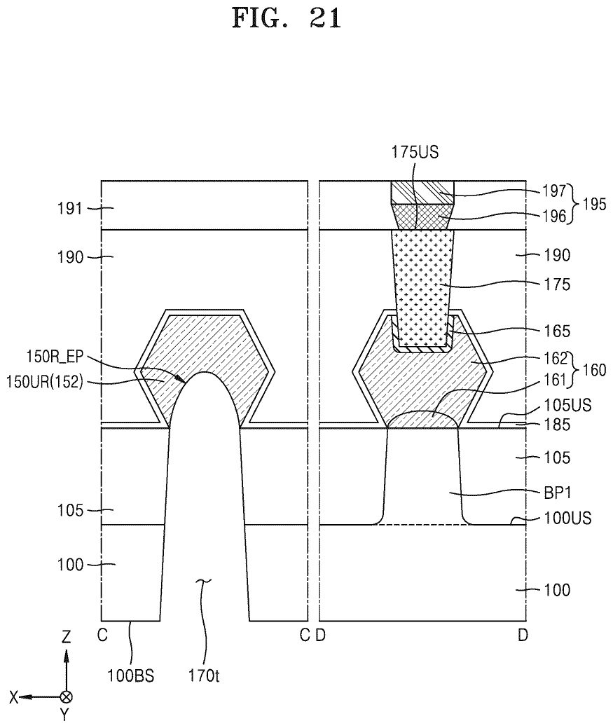

Referring to FIGS. 20 and 21, in some embodiments, the thickness of the substrate 100 may be reduced by removing a portion of the substrate 100 after the wiring structure 195 is formed. Subsequently, the power contact hole 170t may be formed to pass through the substrate 100 and the first fin-type active pattern BP1, and the epitaxial recess 150R_EP may be formed to be inside the upper source/drain region 150UR. The power contact hole 170t may pass through the substrate 100 and the first fin-type active pattern BP1 and may be in communication with the epitaxial recess 150R_EP. The epitaxial recess 150R_EP may expose the upper source/drain region 150UR.

In some embodiments, the power contact hole 170t and the epitaxial recess 150R_EP may be formed through a single etching process. In some embodiments, the power contact hole 170t and the epitaxial recess 150R_EP may be formed by a first etching process, in which the power contact hole 170t passing through the substrate 100 and the first fin-type active pattern BP1 is formed, and a second etching process, in which the epitaxial recess 150R_EP is formed through etching.

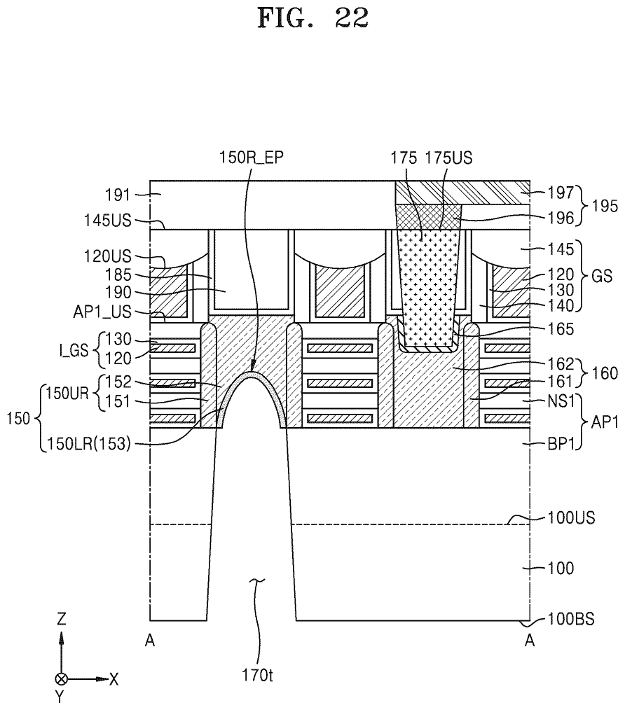

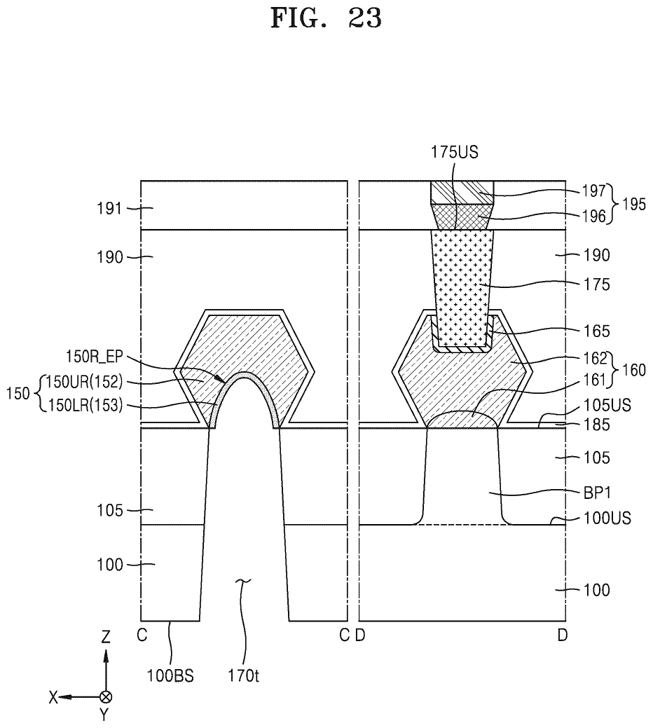

Referring to FIGS. 22 and 23, the lower epitaxial region 153 may be formed along the inner wall of the epitaxial recess 150R_EP. Accordingly, the first source/drain pattern 150 including the upper source/drain region 150UR and the lower source/drain region 150LR may be formed. The lower epitaxial region 153 may be formed by using a selective epitaxial growth method.

Continuously, referring to FIGS. 2 and 4, the first contact silicide film 155 contacting the first source/drain pattern 150 may be formed in the power contact hole 170t. The first source/drain contact 170 connected to the first contact silicide film 155 may be formed in the power contact hole 170t. Subsequently, the first power line 50 and the second power line 60 may be formed on the bottom surface 100BS of the substrate 100.

While inventive concepts have been particularly shown and described with reference to embodiments thereof, it will be understood that various changes in form and details may be made therein without departing from the spirit and scope of the following claims.

What is claimed is:

1. A semiconductor device comprising:
a substrate with a top surface of the substrate being opposite a bottom surface of the substrate in a vertical direction;
an active pattern extending in a first horizontal direction on the top surface of the substrate, the active pattern including a fin-type active pattern protruding from the top surface of the substrate;
a gate electrode on the active pattern and extending in a second horizontal direction, the second horizontal direction being perpendicular to the first horizontal direction;
a first source/drain pattern connected to the fin-type active pattern, the first source/drain pattern including a lower epitaxial region and an upper epitaxial region, the upper epitaxial region including an epitaxial recess that is inwardly recessed from a surface of the fin-type active pattern, and the lower epitaxial region being arranged along an inner wall of the epitaxial recess, wherein the substrate, the fin-type active pattern, and a lower surface of the first source/drain pattern define a power contact hole passing through substrate and the fin-type active pattern;
a first source/drain contact connected to the first source/drain pattern, the first source/drain contact extending through the power contact hole into the epitaxial recess; and
a contact silicide film between the first source/drain contact and the first source/drain pattern, the contact silicide film being on an inner wall of the power contact hole, the contact silicide film being in contact with the lower epitaxial region arranged along the inner wall of the epitaxial recess.

2. The semiconductor device of claim 1, wherein
in a cross-sectional view of the lower epitaxial region, the lower epitaxial region has an oval shape, a triangular shape, or an inverted U-shape.

3. The semiconductor device of claim 1, wherein a distance from the surface of the fin-type active pattern to a topmost surface of the lower epitaxial region is less than or equal to a distance from the topmost surface of the lower epitaxial region to a top surface of the upper epitaxial region.

4. The semiconductor device of claim 1, wherein a distance from the surface of the fin-type active pattern to a topmost surface of the lower epitaxial region is greater than a distance from the topmost surface of the lower epitaxial region to a top surface of the upper epitaxial region.

5. The semiconductor device of claim 1, wherein
the lower epitaxial region and the upper epitaxial region include a silicon-germanium compound, and a concentration of germanium in the lower epitaxial region is less than a concentration of germanium in the upper epitaxial region.

6. The semiconductor device of claim 1, wherein the contact silicide film is continuously arranged along the inner wall of the epitaxial recess and the inner wall of the power contact hole.

7. The semiconductor device of claim 1, further comprising:
a power line on the bottom surface of the substrate, wherein the first source/drain contact electrically connects the first source/drain pattern and the power line to each other.

8. The semiconductor device of claim 1, further comprising:
a second source/drain pattern on the fin-type active pattern,
a wiring structure above the top surface of the substrate, and
a second source/drain contact connecting the wiring structure to the second source/drain pattern.

9. The semiconductor device of claim 8, wherein the gate electrode is between the first source/drain pattern and the second source/drain pattern.

10. A semiconductor device comprising:
a substrate with a top surface of the substrate being opposite a bottom surface of the substrate in a vertical direction;
an active pattern extending in a first horizontal direction on the top surface of the substrate, the active pattern including a fin-type active pattern protruding from the top surface of the substrate;
a gate electrode on the active pattern and extending in a second horizontal direction, the second horizontal direction being perpendicular to the first horizontal direction;
a first source/drain pattern connected to the fin-type active pattern,
the first source/drain pattern including a cylindrical epitaxial region, a lower epitaxial region, and an upper epitaxial region in the cylindrical epitaxial region, the cylindrical epitaxial region being arranged on the fin-type active pattern,
the upper epitaxial region including an epitaxial recess that is inwardly recessed from a surface of the fin-type active pattern, and
the lower epitaxial region being arranged along an inner wall of the epitaxial recess,
wherein the substrate, the fin-type active pattern, and a lower surface of the first source/drain pattern define a power contact hole passing through the substrate and the fin-type active pattern;
a first source/drain contact connected to the first source/drain pattern, the first source/drain contact extending through the power contact hole into the epitaxial recess; and
a contact silicide film between the first source/drain contact and the first source/drain pattern, the contact silicide film being on an inner wall of the power contact hole, the contact silicide film being in contact with the lower epitaxial region arranged along the inner wall of the epitaxial recess.

11. The semiconductor device of claim 10, wherein
in a cross-sectional view of the lower epitaxial region, the lower epitaxial region has an oval shape, a triangular shape, or an inverted U-shape.

12. The semiconductor device of claim 10, wherein a distance from the surface of the fin-type active pattern to a topmost surface of the lower epitaxial region is less than or equal to a distance from the topmost surface of the lower epitaxial region to a top surface of the upper epitaxial region.

13. The semiconductor device of claim 10, wherein a distance from the surface of the fin-type active pattern to a topmost surface of the lower epitaxial region is greater than a distance from the topmost surface of the lower epitaxial region to a top surface of the upper epitaxial region.

14. The semiconductor device of claim 10, wherein
the cylindrical epitaxial region, the lower epitaxial region, and the upper epitaxial region include a silicon-germanium compound, and
a concentration of germanium in each of the cylindrical epitaxial region and the lower epitaxial region is less than a concentration of germanium in the upper epitaxial region.

15. The semiconductor device of claim 10, wherein the contact silicide film is continuously arranged along the inner wall of the epitaxial recess and the inner wall of the power contact hole.

16. The semiconductor device of claim 10, further comprising:
a second source/drain pattern on the fin-type active pattern,
a wiring structure above the top surface of the substrate, and
a second source/drain contact connecting the wiring structure to the second source/drain pattern.

17. A semiconductor device comprising:
a substrate with a top surface of the substrate being opposite a bottom surface of the substrate in a vertical direction;
an active pattern extending in a first horizontal direction on the top surface of the substrate, the active pattern including a fin-type active pattern and a sheet-type active pattern on the fin-type active pattern, the fin-type active pattern protruding from the top surface of the substrate, a first end of the sheet-type active pattern being opposite a second end of the sheet-type active pattern in the first horizontal direction;
a gate electrode on the active pattern, the gate electrode extending in a second horizontal direction and surrounding the sheet-type active pattern, the second horizontal direction being perpendicular to the first horizontal direction;
a first source/drain pattern connected to the fin-type active pattern and connected to the first end of the sheet-type active pattern, the first source/drain pattern including a lower epitaxial region and a first upper epitaxial region, the first upper epitaxial region including an epitaxial recess that is inwardly recessed from a surface of the fin-type active pattern, and the lower epitaxial region being arranged along an inner wall of the epitaxial recess,
wherein the substrate, the fin-type active pattern, and a lower surface of the first source/drain pattern define a power contact hole passing through the substrate and the fin-type active pattern;
a second source/drain pattern in contact with the fin-type active pattern and connected to the second end of the sheet-type active pattern, the second source/drain pattern including a second upper epitaxial region;
a first source/drain contact connected to the first source/drain pattern, the first source/drain contact extending through the power contact hole into the epitaxial recess;
a second source/drain contact on the fin-type active pattern and connected to the second source/drain pattern;
a first contact silicide film between the first source/drain contact and the first source/drain pattern, the first contact silicide film being on an inner wall of the power contact hole, the first contact silicide film being in contact with the lower epitaxial region arranged along the inner wall of the epitaxial recess; and
a second contact silicide film between the second source/drain contact and the second source/drain pattern, the second contact silicide film being in contact with the second upper epitaxial region.

18. The semiconductor device of claim 17, wherein
in a cross-sectional view of the lower epitaxial region, the lower epitaxial region has an oval shape, a triangular shape, or an inverted U-shape, and
a distance from the surface of the fin-type active pattern to a topmost surface of the lower epitaxial region is less than or equal to a distance from the topmost surface of the lower epitaxial region to a top surface of the first upper epitaxial region.

19. The semiconductor device of claim 17, wherein
in a cross-sectional view of the lower epitaxial region, the lower epitaxial region has an oval shape, a triangular shape, or an inverted U-shape, and
a distance from the surface of the fin-type active pattern to a topmost surface of the lower epitaxial region is greater than a distance from the topmost surface of the lower epitaxial region to a top surface of the first upper epitaxial region.

20. The semiconductor device of claim 17, wherein the first contact silicide film is continuously arranged along the inner wall of the epitaxial recess and the inner wall of the power contact hole.
